(19) United States
(12) Patent Application Publication
(10) Pub. No.: US 2025/0248082 A1
(43) Pub. Date: Jul. 31, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventor: Katsumi NAKAMURA, Tokyo (JP)

(73) Assignee: Mitsubishi Electric Corporation, Tokyo (JP)

(21) Appl. No.: 18/913,572

(22) Filed: Oct. 11, 2024

(30) Foreign Application Priority Data
Jan. 25, 2024 (JP) 2024-009286

(51) Int. Cl. H01L 29/06; H01L 29/66; H01L 29/739

(52) U.S. Cl. CPC H10D 62/111; H10D 12/038; H10D 12/481

(57) ABSTRACT

A semiconductor device includes a semiconductor substrate, a first electrode, and a second electrode. The semiconductor substrate includes a drift layer, a semiconductor layer, a first buffer layer, and a second buffer layer. When a maximum value of an oxygen concentration of the semiconductor substrate calculated using a conversion factor of Old ASTM is maximum [Oᵢ] and an impurity concentration of a first conductive type of the drift layer is C_{drift}, maximum [Oᵢ]=9.40×10¹⁶×ln(C_{drift})−2.27×10¹⁸ is satisfied.

### BACKGROUND OF THE INVENTION

### Field of the Invention

The present disclosure relates to a semiconductor device and a method of manufacturing the semiconductor device.

### Description of the Background Art

There has been proposed a configuration in which a broad profile layer having a maximum impurity concentration is provided in a vicinity of a center of a drift layer of a power diode or in a vicinity of a collector of an insulated gate bipolar transistor (IGBT) (for example, Japanese Patent Application Laid-Open No. 2014-99643). According to this configuration, a withstand voltage, which is basic performance of the semiconductor device, and electric field intensity on a back surface side (cathode or collector) during turn-off operation can be controlled even when specific resistance of a semiconductor wafer, namely, the concentration of the drift layer varies. Thus, a carrier can remain on the back surface side, and an oscillation phenomenon during the turn-off operation can be prevented, so that controllability during a dynamic operation can be improved.

In a manufacturing process, heat treatment in an atmosphere containing oxygen or heat treatment after a thermal oxide film is formed forms a profile in which an oxygen concentration decreases in a depth direction of the semiconductor wafer because oxygen is diffused into the semiconductor wafer. On the other hand, a donor layer derived from hydrogen such as a proton provided in Japanese Patent Application Laid-Open No. 2014-99643 or the like is easily affected by oxygen in the semiconductor wafer.

For this reason, an impurity profile of the donor layer changes unstably in the depth direction due to the profile in which the oxygen concentration decreases in the depth direction, or the impurity concentration of the donor layer increases due to a thermal donor phenomenon caused by oxygen. As a result, there is a problem that the donor layer cannot be formed as designed, and a withstand voltage characteristic and a switching characteristic become unstable.

### SUMMARY

The present disclosure has been made in view of the above problems, and an object of the present disclosure is to provide a technique capable of stabilizing the withstand voltage characteristic and the switching characteristic.

A semiconductor device according to the present disclosure includes: a semiconductor substrate including a first main surface and a second main surface opposite to the first main surface; and a first electrode and a second electrode that are provided on the first main surface and the second main surface, respectively, in which the semiconductor substrate includes: a first conductive type drift layer provided between the first main surface and the second main surface; a semiconductor layer that is connected to the second electrode and includes at least one of a first conductive type first semiconductor layer and a second conductive type second semiconductor layer; a first conductive type first buffer layer provided between the semiconductor layer and the drift layer; and a first conductive type second buffer layer that is provided between the first buffer layer and the drift layer and in which a first conductive type impurity concentration is smaller than that of the first buffer layer and is greater than that of the drift layer, and, when a maximum value of an oxygen concentration of the semiconductor substrate calculated using a conversion factor of Old ASTM is maximum [Oᵢ], and an impurity concentration of the first conductive type drift layer is C_{drift}, maximum [Oᵢ]=9.40×10¹⁶×ln(C_{drift})−2.27×10¹⁸ is satisfied.

The withstand voltage characteristic and the switching characteristic can be stabilized.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a semiconductor device according to a first preferred embodiment;

FIG. 2 is a sectional view illustrating configurations of an IGBT and a diode according to the first preferred embodiment;

FIG. 3 is a view illustrating a relationship between an oxygen concentration [Oᵢ] of a semiconductor substrate and an impurity concentration C_{drift} of an n⁻-type drift layer;

FIG. 4 is a view illustrating a measurement result of an impurity profile taken along line B-B′ in FIG. 2 according to the first preferred embodiment;

FIG. 5 is a view illustrating a relationship between an electrostatic breakdown voltage (BV_{ces}) of the IGBT having an n-type second buffer layer of a profile (new structure 1) and the oxygen concentration ([Oᵢ]) in an MCZ wafer according to the first preferred embodiment;

FIG. 6 is a view illustrating a relationship between a time-zero dielectric breakdown characteristic of a gate oxide film and the oxygen concentration ([Oᵢ]) in the MCZ wafer;

FIG. 7 is a view illustrating an output characteristic of the IGBT;

FIG. 8 is a view illustrating operation temperature dependency of an on-voltage (V_{CE}(sat)) of the IGBT;

FIG. 9 is a view illustrating the operating temperature dependency of the breakdown voltage (BV_{CES}) of the IGBT;

FIG. 10 is a view illustrating a relationship between maximum cutoff energy (E_{SC}) and on-voltage (V_{CE}(sat)) in a short-circuit state of the IGBT;

FIG. 11 is a view illustrating a trade-off characteristic between a switching loss (E_{REC}) and an on-voltage (V_{F}) of a diode;

FIG. 12 is a view illustrating a relationship between maximum interruption power density of a diode at turn-off and a maximum switching speed (dj/dt) of the diode at turn-off;

FIG. 13 is a view illustrating a measurement result of the impurity profile taken along line B-B″ in FIG. 2 according to a second preferred embodiment;

FIG. 14 is a view illustrating a device characteristic of a diode (b);

FIG. 15 is a view illustrating a relationship between diode performance and a maximum peak value C₂ in the n-type second buffer layer;

FIG. 16 is a view illustrating a relationship between the diode performance and C₂/C₁;

FIG. 17 is a view illustrating a measurement result of the impurity profile taken along line B-B′ in FIG. 2 according to a third preferred embodiment;

FIG. 18 is a view illustrating a relationship between the maximum cutoff energy (E_{SC}) and a power supply voltage (V_{CC}) in the short-circuit state of the IGBT;

FIG. 19 is a view illustrating a simulation result of a device internal state of the IGBT;

FIG. 20 is a view illustrating a relationship between the maximum cutoff energy (E_{SC}) in the short-circuit state of the IGBT and a depth X₂ of a peak of an n-type impurity concentration in the n-type second buffer layer;

FIGS. 21A to 21F, 22G to 22J, and 23K to 23M are sectional views illustrating processes of a manufacturing method according to a fourth preferred embodiment;

FIG. 24 is a flowchart illustrating some processes of the manufacturing method according to the fourth preferred embodiment;

FIGS. 25A to 25C, 26D to 26F, and 27G to 271 are sectional views illustrating processes of a manufacturing method according to a fifth preferred embodiment;

FIGS. 28 and 29 are flowcharts illustrating some processes of the manufacturing method according to the fifth preferred embodiment; and

FIGS. 30 to 37 are sectional views illustrating a configuration of a semiconductor device according to a sixth preferred embodiment.

### DESCRIPTION OF THE PREFERRED EMBODIMENTS

Hereinafter, preferred embodiments will be described with reference to the accompanying drawings. Features described in the following preferred embodiments are examples, and all features are not necessarily essential. In the following description, similar components in a plurality of preferred embodiments are denoted by the same or similar reference numerals, and different components will be mainly described. Furthermore, in the following description, specific positions and directions such as “upper”, “lower”, “left”, “right”, “front”, or “back” may not necessarily coincide with actual positions and directions in practice. In addition, the fact that concentration of a certain portion is higher than that of another portion may mean that, for example, the average of the concentration of the certain portion is higher than the average of the concentration of another portion. Conversely, the fact that concentration of a certain portion is lower than that of another portion may mean that, for example, the average of the concentration of the certain portion is lower than the average of the concentration of another portion. In the following description, e first conductive type is n-type and e second conductive type is p-type, but the first conductive type may be p-type and the second conductive type may be n-type.

### First Preferred Embodiment

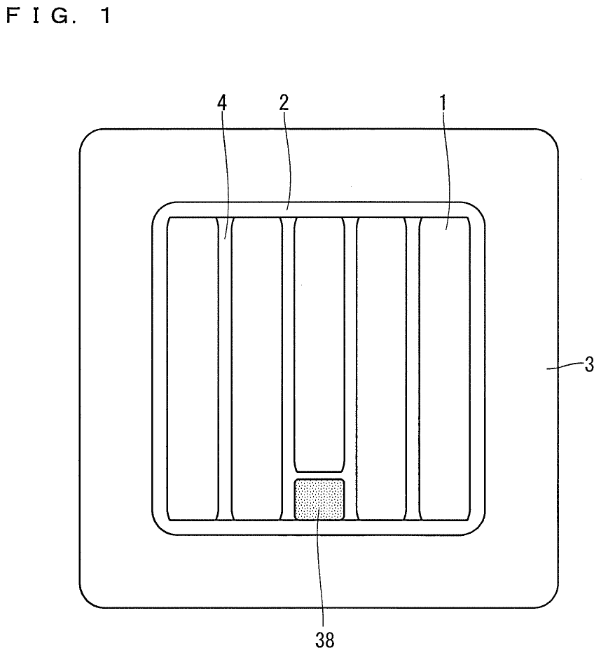

FIG. 1 is a plan view illustrating a configuration of a power semiconductor chip that is an example of a semiconductor device according to a first preferred embodiment. An active region 1, an interface region 2, and a termination region 3 are defined in the semiconductor device of FIG. 1.

The active region 1 is a region that ensures basic performance of the semiconductor device, and an IGBT that is a first semiconductor device or a diode that is a second semiconductor device is provided as a semiconductor element. The interface region 2 is a region between the active region 1 and the termination region 3, and is a region that supports breakdown resistance during a dynamic operation of the semiconductor device or supports original performance of the semiconductor element provided in the active region 1. The termination region 3 is a region that ensures withstand voltage retention and stability and reliability of a withstand voltage characteristic in a static state, prevents a breakdown resistance failure during the dynamic operation, and supports basic performance of the semiconductor device.

In FIG. 1, the IGBT is provided in the active region 1, and a surface gate wiring portion 4 and a gate pad portion 38 are provided in the active region 1. When a diode is provided in the active region 1, the surface gate wiring portion 4 and the gate pad portion 38 may not be provided in the active region 1.

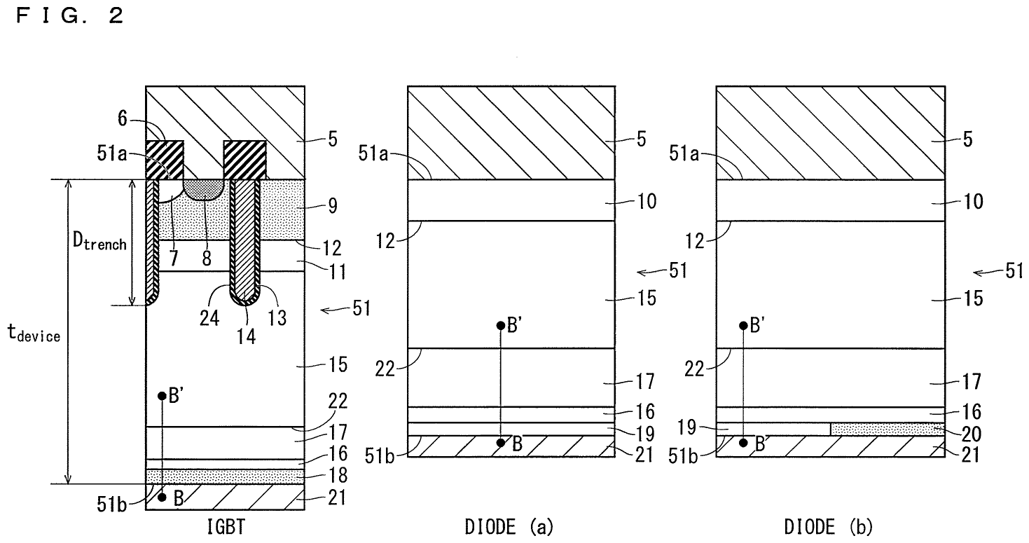

FIG. 2 is a sectional view illustrating configurations of the IGBT and the diode according to the first preferred embodiment. FIG. 2 illustrates one type of IBGT and two types of diodes (a diode (a) and a diode (b)). The diode that is a second semiconductor device may be the diode (a) that is a diode having a p-i-n structure or the diode (b) that is a diode having a relaxed field of cathode (RFC) structure. The name of the diode that is the second semiconductor device may be a power diode or a freewheeling diode (FWD).

First, among components of the one type of IGBT, components common to two types of diodes will be mainly described. The IGBT includes a semiconductor substrate 51, a first electrode 5, and a second electrode 21.

The semiconductor substrate 51 includes a front surface 51a as a first main surface and a back surface 51b as a second main surface opposite to the first main surface. The first electrode 5 is provided on the front surface 51a, and for example, is included in aluminum wiring. The second electrode 21 is provided on the back surface 51b, and for example, is included in a metal film. For example, a final device thickness (t_{device}) corresponding to a thickness of the semiconductor substrate 51 is 40 μm to 700 μm.

The semiconductor substrate 51 according to the first preferred embodiment is a semiconductor wafer of silicon (Si) (hereinafter, also referred to as an “MCZ wafer”) manufactured by a magnetic field applied Czochralski (MCZ) method. Oxygen and carbon introduced as impurities during manufacturing the MCZ wafer exist at an interstitial position and a lattice position substitution position in a Si single crystal, respectively. Accordingly, in the following description, an oxygen concentration and a nitrogen concentration of the semiconductor substrate 51 are referred to as [Oᵢ] and [Cₛ], respectively, with first letters of interstitial and substitutional. In general, [Oᵢ] of the MCZ wafer is higher than [Oᵢ] of a floating zone (FZ) wafer by two to three orders of magnitude, but [Cₛ] of the MCZ wafer and [Cₛ] of the FZ wafer are equivalent.

The semiconductor substrate 51 includes an n⁻-type drift layer 15 that is a drift layer of the first conductive type, an n-type first buffer layer 16 that is a first buffer layer of the first conductive type, an n-type second buffer layer 17 that is a second buffer layer of the first conductive type, and a semiconductor layer described later. In the present specification, the impurity concentration is a concentration of an element different from Si, and the element will be described as appropriate. In the first preferred embodiment, the element forming a diffusion layer is a dopant.

The n⁻-type drift layer 15 corresponds to a portion of the MCZ wafer that is the semiconductor substrate 51 into which impurities (Ions, dopants) are not substantially newly implanted. For example, the n-type impurity of the n⁻-type drift layer 15 is phosphorus (P) or antimony (Sb), and an impurity concentration C_{drift} of the n⁻-type drift layer 15 is 1.0×10¹² atoms/cm³ to 5.0×10¹⁴ atoms/cm³.

Incidentally, during manufacturing the semiconductor wafer having a large diameter, the impurity concentration in a crystal axis direction of a Si single crystal ingot (that is, the impurity concentration C_{drift} of the n⁻-type drift layer 15) largely varies due to a segregation phenomenon of the dopant in the Si single crystal ingot. However, an evaporation rate of antimony (1.3×10⁻¹ cm/sec) is higher than the evaporation rate of phosphorus (1.6×10⁻⁴ cm/sec) by about 3 orders of magnitude. For this reason, when antimony is used as the n-type impurity of the semiconductor wafer, and when the Si single crystal is produced by an evaporation control technique utilizing the characteristics thereof, variations in the impurity concentration C_{drift} in the crystal axis direction of the Si single crystal ingot can be prevented.

The n⁻-type drift layer 15 is provided between the front surface 51a and the back surface 51b, and, for example, is provided from a main junction 12 on the side of the front surface 51a to a junction portion 22 on the side of the back surface 51b. When voltage of the semiconductor element is held, a reverse bias is applied to the main junction 12. When the reverse bias is applied to the main junction 12, a depletion layer extends from the main junction 12 to the back surface 51b, and electric field strength is maximized at the main junction 12. The junction portion 22 is a portion in contact with the depletion layer extending from the main junction 12 to the back surface 51b during voltage holding, and is a portion where the electric field strength becomes second highest after the main junction during voltage holding.

The semiconductor layer is connected to the second electrode 21, and includes at least one of a first semiconductor layer of the first conductive type and a second semiconductor layer of the second conductive type. In the present specification, for example, at least one of A, B, C, . . . , and Z means any one of all combinations extracted from group of A, B, C, . . . , and Z.

The semiconductor layer of the IGBT includes a p-type collector layer 18 that is the second semiconductor layer of the second conductive type. In the p-type collector layer 18, for example, the p-type impurity is boron (B), a peak value of the impurity concentration is 1.0×10¹⁶ atoms/cm³ to 1.0×10²¹ atoms/cm³, and the depth from the back surface 51b is 0.3 μm to 0.8 μm.

The semiconductor layer of the diode (a) includes an n⁺-type cathode layer 19 that is the first semiconductor layer of the first conductive type. In the n⁺-type cathode layer 19, for example, the n-type impurity is arsenic (As) or phosphorus (P), the peak value of the impurity concentration is 1.0×10¹⁷ atoms/cm³ to 1.0×10¹⁹ atoms/cm³, and the depth from the back surface 51b is 0.3 μm to 0.5 μm.

The semiconductor layer of the diode (b) includes the n⁺-type cathode layer 19 that is the first semiconductor layer of the first conductive type and a p-type cathode layer 20 that is the second semiconductor layer of the second conductive type. The n⁺-type cathode layer 19 of the diode (b) is similar to the n⁺-type cathode layer 19 of the diode (a). In the p-type cathode layer 20, for example, the p-type impurity is boron (B), the peak value of the impurity concentration is 1.0×10¹⁶ atoms/cm³ to 1.0×10¹⁸ atoms/cm³, and the depth from the back surface 51b is 0.3 μm to 0.5 μm.

The two buffer layers (the n-type first buffer layer 16 and the n-type second buffer layer 17) are provided for stabilizing voltage holding capability in an off-state, reducing the power consumption at the time of off, and improving controllability and the breakdown resistance during the dynamic operation. For example, the n-type first buffer layer 16 is provided for stabilizing the voltage holding capability in the off-state.

The n-type first buffer layer 16 is provided between the semiconductor layer connected to the second electrode 21 and the n⁻-type drift layer 15. For example, the n-type first buffer layer 16 of the IGBT is provided between the p-type collector layer 18 and the n⁻-type drift layer 15. The n-type first buffer layer 16 of the diode (a) is provided between the n⁺-type cathode layer 19 and the n⁻-type drift layer 15. The n-type first buffer layer 16 of the diode (b) is provided between each of the n⁺-type cathode layer 19 and the p-type cathode layer 20 and the n⁻-type drift layer 15.

In the n-type first buffer layer 16, for example, the n-type impurity is arsenic (As) or phosphorus (P), a maximum peak value (C₁) of the impurity concentration is 1.0×10¹⁵ atoms/cm³ to 5.0×10¹⁶ atoms/cm³, and a depth (X₁) from the back surface 51b is 1.0 μm to 30 μm.

The n-type second buffer layer 17 is provided between the n-type first buffer layer 16 and the n⁻-type drift layer 15. The n-type impurity concentration of the n-type second buffer layer 17 is lower than the n-type impurity concentration of the n-type first buffer layer 16 and higher than the n-type impurity concentration of the n⁻-type drift layer 15.

In the n-type second buffer layer 17, for example, the n-type impurity is proton (H⁺), a maximum peak value (C₂) of the impurity concentration is less than C₁ described above, preferably less than or equal to 0.01×C₁, and a depth (X₂) from the back surface 51b is 20 μm to 30 μm deeper than the depth (X₁).

As will be described later, a relationship of τ₂<τ₁≤τₜ may be satisfied for the n⁻-type drift layer 15, the n-type first buffer layer 16, and the n-type second buffer layer 17. At this point, τ₂ is a carrier lifetime of the n-type second buffer layer 17, and τ₁ is the carrier lifetime of the n-type first buffer layer 16. τₜ is the carrier lifetime of the n⁻-type drift layer 15 without affecting the on-voltage of the IGBT (that is, the on-voltage of the gate electrode).

Other components of the IGBT will be described below. The semiconductor substrate 51 further includes an n⁺-type emitter layer 7 that is an emitter layer of the first conductive type, a p⁺-type layer 8, a p-type base layer 9 that is a base layer of the second conductive type, and an n-type layer 11.

The p-type base layer 9 is provided closer to the front surface 51a than the n⁻-type drift layer 15. In the p-type base layer 9, for example, the p-type impurity is boron (B), the peak value of the impurity concentration is 1.0×10¹⁶ atoms/cm³ to 1.0×10¹⁸ atoms/cm³, and the depth from the front surface 51a is deeper than the n⁺-type emitter layer 7 and shallower than the n-type layer 11.

The n-type layer 11 is provided between the p-type base layer 9 and the n⁻-type drift layer 15. In the n-type layer 11, for example, the n-type impurity is arsenic (As) or phosphorus (P), the peak value of the impurity concentration is 1.0×10¹5 atoms/cm³ to 1.0×10¹⁷ atoms/cm³, and the depth from the front surface 51a is 0.5 μm to 1.0 μm deeper than that of the p-type base layer 9.

The n⁺-type emitter layer 7 is provided closer to the front surface 51a than the p-type base layer 9. In the n⁺-type emitter layer 7, for example, the n-type impurity is arsenic (As) or phosphorus (P), the peak value of the impurity concentration is 1.0×10¹⁸ atoms/cm³ to 1.0×10²¹ atoms/cm³, and the depth from the front surface 51a is 0.2 m to 1.0 km.

The p⁺-type layer 8 is provided closer to the front surface 51a than the p-type base layer 9. In the p⁺-type layer 8, for example, the p-type impurity is boron (B), the surface impurity concentration is 1.0×10¹⁸ atoms/cm³ to 1.0×10²¹ atoms/cm³, and the depth from the front surface 51a is the same as or deeper than that of the n⁺-type emitter layer 7.

A trench 24 penetrating the p-type base layer 9, the n⁺-type emitter layer 7, and the n-type layer 11 is provided in the semiconductor substrate 51 of the IGBT. For example, a depth D_{trench} of the trench 24 from the front surface 51a is greater than or equal to μ2.0 μm, and is deeper than the n-type layer 11.

On the inner wall of the trench 24, a gate electrode 14 that is a trench electrode is provided through a gate oxide film 13. The gate electrode 14 is electrically connected to the surface gate wiring portion 4 in FIG. 1, and insulated from the first electrode 5 at the emitter potential by the interlayer film 6 including an oxide film and the like. As described later, the trench electrode provided in the trench 24 may further include a dummy electrode connected to the first electrode 5 at the emitter potential in addition to the gate electrode 14. When the trench electrode includes the dummy electrode, restraint of oscillation and improvement of short-circuit resistance in an unloaded short-circuit state can be expected by restraint of saturation current density and control of a capacitance characteristic of the IGBT, and reduction in on-voltage can be expected by improvement of carrier concentration on the emitter side.

Other components of the diode (a) and the diode (b) will be described below. As described above, the difference between the diode (a) and the diode (b) is the presence or absence of the p-type cathode layer 20.

The semiconductor substrate 51 further includes a p-type anode layer 10 that is an anode layer of the second conductive type. The p-type anode layer 10 is provided closer to the front surface 51a than the n⁻-type drift layer 15. In the p-type anode layer 10, for example, the p-type impurity is boron (B), the surface impurity concentration is greater than or equal to 1.0×10¹⁶ atoms/cm³, and the peak value of the impurity concentration is 2.0×10¹⁶ atoms/cm³ to 1.0×10¹⁸ atoms/cm³. For example, the depth from the front surface 51a of the p-type anode layer 10 is 2.0 μm to 10.0 μm.

As will be described later, the p⁺-type layer 8, which is the second conductive type impurity diffusion layer that is provided closer to the front surface 51a than the p-type anode layer 10 and has a higher p-type impurity concentration than the p-type anode layer 10, may be provided similarly to the p⁺-type layer 8 of the IGBT.

In addition to the n⁻-type drift layer 15, the n-type first buffer layer 16, and the n-type second buffer layer 17, the p-type collector layer 18, the n⁺-type cathode layer 19, and the p-type cathode layer 20 form a vertical structure. The vertical structure is a region that ensures stability and reliability of total loss (a loss obtained by adding a loss of an on-voltage in an on-state, a loss of a turn-on state, and a loss of a turn-off state) performance, the withstand voltage retention and the withstand voltage characteristic in the static state, and leakage characteristics (off-loss) at the time of holding the voltage at a high temperature. In addition, the vertical structure is a region that ensures controllability and breakdown resistance during dynamic operation and supports basic performance of the semiconductor device.

In the manufacturing process of the semiconductor wafer of Si constituting the IGBT and the diode described above, when the oxygen is introduced into the semiconductor wafer, the oxygen becomes donor at a specific annealing temperature due to a thermal donor phenomenon, and a n-type impurity concentration C_{drift} of the n⁻-type drift layer 15 increases. In particular, the n-type impurity concentration C_{drift} of the MCZ wafer is significantly increased as compared with the semiconductor wafer of the FZ method.

In the first preferred embodiment, in order to solve the problem caused by this, the following formula (1) is satisfied when the maximum value of the oxygen concentration of the semiconductor substrate 51 is set to maximum [Oᵢ].

maximum[Oᵢ]=9.40×10¹⁶×ln(C_{drift})−2.27×10¹⁸ (1)

[Oᵢ] in the formula (1) is calculated using a detection value obtained by detecting the oxygen in Si by Fourier transform infrared spectroscopy (FTIR) and a conversion factor adopted in F121-79 (Old ASTM) of ASTM (American Society for Testing and Materials). For example, the impurity concentration C_{drift} is a representative value (for example, an average value, an intermediate value, and the like) of the n-type impurity concentration in the n⁻-type drift layer 15. The units of [Oᵢ] and the impurity concentration C_{drift} are the same (for example, [cm⁻³]), and ln is the natural logarithm.

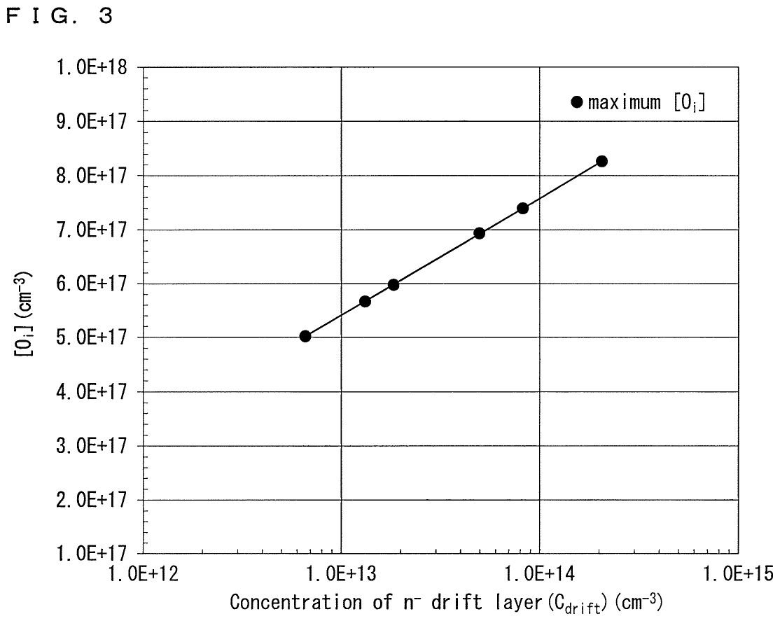

FIG. 3 is a view illustrating a relationship between the oxygen concentration [Oᵢ] of the semiconductor substrate 51 that is the MCZ wafer and the impurity concentration C_{drift} of the n⁻-type drift layer 15 in the formula (1).

According to the configuration of the first preferred embodiment satisfying this relationship, even when the impurity concentration C_{drift} of the n⁻-type drift layer 15 changes due to the thermal donor phenomenon, an adverse effect on the off-state voltage (electrostatic breakdown voltage) retention capability that is the basic performance of the semiconductor device can be prevented. In addition, the adverse effects such as instability and change of an impurity profile of the n-type second buffer layer 17 caused by the oxygen can be prevented. In particular, when the semiconductor substrate 51 is the MCZ wafer having a uniform oxygen concentration profile, this adverse effect is effectively prevented. The maximum [Oᵢ] can be paraphrased as a limit value of [Oᵢ] that maintains the off-state voltage holding capability when the impurity concentration C_{drift} of the n⁻-type drift layer 15 changes due to oxygen-induced thermal donation in the MCZ wafer.

[Oᵢ] in the formula (1) is calculated using the conversion factor of Old ASTM as described above. When [Oᵢ] is calculated using the conversion factor of ASTM F121-83 (New ASTM), the following formula (2) may be satisfied. When [Oᵢ] is calculated using the conversion factor of International Oxygen Coefficient 1988 (IOC 88), the following formula (3) may be satisfied.

maximum[Oᵢ]=4.78×10¹⁶×ln(C_{drift})−1.16×10¹⁸ (2)

maximum[Oᵢ]=6.13×10¹⁶×ln(C_{drift})−1.48×10¹⁸ (3)

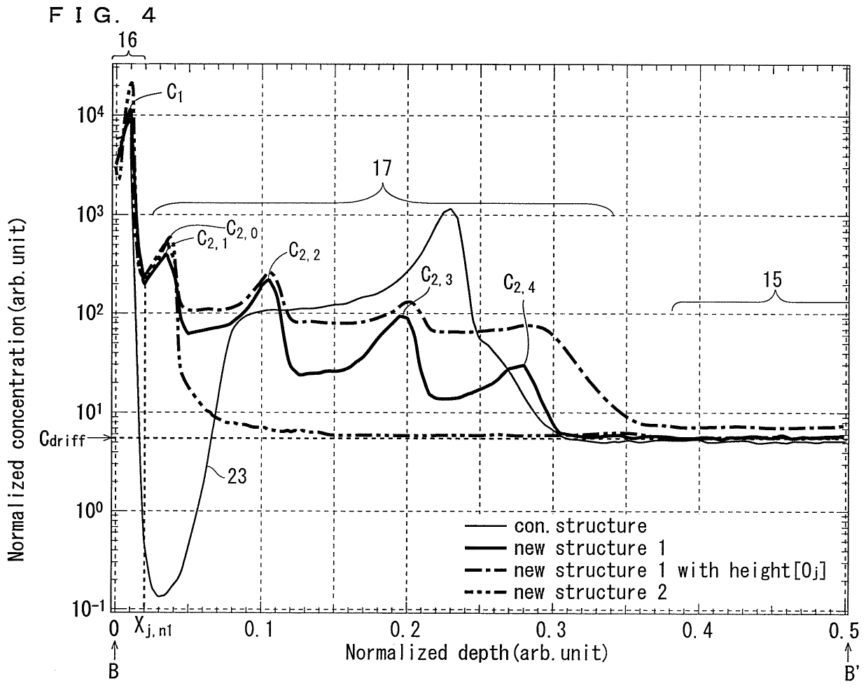

FIG. 4 is a view illustrating a measurement result of the impurity profile in the depth direction taken along line B-B′ in FIG. 2 according to the first preferred embodiment. FIG. 4 illustrates the result measured by a spreading resistance analysis (SRA) method, and the impurity concentration of the p-type collector layer 18 is not detected with measurement accuracy of SRA.

FIG. 4 illustrates the impurity profiles of a new structure 1, a new structure 2, a new structure with height [Oᵢ], and a con. structure.

The new structure 1 and the new structure 2 are the impurity profiles of the semiconductor device formed from the semiconductor substrate 51 satisfying the formula (1).

In the new structure 1, the n-type second buffer layer 17 includes a second-1 buffer layer to a second-n buffer layer. The second-1 buffer layer to the second-n buffer layer are provided in order from the n-type first buffer layer 16 toward the n⁻-type drift layer 15, and each have C_{2,1} to C_{2,n} as a peak value of the n-type impurity concentration. When the maximum peak value of the n-type impurity concentration in the n-type second buffer layer 17 in the new structure 1 is C₂, C₂ corresponds to C_{2,1}. The new structure 1 will be described in first and second preferred embodiments.

In the new structure 2, the n-type second buffer layer 17 is a single layer having C_{2,0} as the peak value of the n-type impurity concentration. When the maximum peak value of the n-type impurity concentration in the n-type second buffer layer 17 in the new structure 2 is C₂, C₂ corresponds to C_{2,0}. The new structure 2 will be described in a third preferred embodiment.

The new structure with height [Oᵢ] is the impurity profile of the same semiconductor device as that of the new structure 1 except that the formula (1) is not satisfied. Normally, even in the MCZ wafer in which the impurity profile of [Oᵢ] is substantially constant in the depth direction of the horizontal axis in FIG. 4, the thermal donor phenomenon caused by the oxygen in the semiconductor wafer is generated. However, when [Oᵢ] is higher than the maximum [Oᵢ], as compared with the case where [Oᵢ] is less than or equal to the maximum [Oᵢ], the impurity profile of the n-type second buffer layer 17 becomes broad in the depth direction, and the impurity concentration of the n-type second buffer layer 17 increases.

As a result, it is expected that the impurity profile of the new structure 1 in FIG. 4 cannot be stably implemented in the n-type second buffer layer 17. For this reason, from the viewpoint of stabilizing the impurity profile of the n-type second buffer layer 17, [Oᵢ] is required to be less than or equal to the maximum [Oᵢ] even in the MCZ wafer in which the impurity profile of [Oᵢ] is substantially constant in the depth direction of the junction portion.

On the other hand, in the first preferred embodiment, the n-type buffer layer includes the n-type first buffer layer 16 and the n-type second buffer layer 17, and the semiconductor substrate 51 includes the MCZ wafer in which [Oᵢ] in the n-type second buffer layer 17, or the like is controlled to be less than or equal to the maximum [Of]. For this reason, the impurity profile of the n-type second buffer layer 17 can be stabilized.

The n-type second buffer layer 17 is a hydrogen-induced donors (HDs) layer in which a donor type complex defect formed by reaction between hydrogen and a point defect derived from an interstitial Si pair (I_{Si}) generated during introduction of a proton (H⁺) into Si exists. For example, the point defect includes a G center (I_{Si3} cluster, 1.019 eV(*), E_{V}+0.1 eV) and an X center (I_{Si4} cluster, 1.040 eV(*), E_{V}+0.32 eV). The energy value attached with (*) is photon energy calculated from a PL spectrum when analyzed by a photoluminescence (PL) method. The PL method is an analysis method for irradiating a semiconductor with light and observing light emitted when electron-hole pairs are recombined via a defect level.

The con. structure is the impurity profile of the conventional semiconductor device, and a crystal defect layer 23 having a concentration lower than the impurity concentration C_{drift} of the n⁻-type drift layer 15 is provided in the vicinity of a junction portion (X_{j,n1}) between the n-type first buffer layer 16 and the n-type second buffer layer 17.

Similar to the HDs layer of the n-type second buffer layer 17, point defects (the G center and the X center) derived from the interstitial Si pairs exist as defects of the crystal defect layer 23. However, the con. structure that is not supplied with protons (H⁺) is short of hydrogen, so that the point defect and hydrogen do not react with each other, and the HDs layer is not formed. In addition, as [Oᵢ] is higher, H⁺ is trapped by complex defects (for example, VO (vacancy-oxygen pair), CiOi (interstitial carbon-interstitial oxygen pair), V₂ (di-Vacancy)) caused by oxygen in Si to become VOH, CᵢOᵢHₙ, and V₂H₂, and diffusion of H⁺ in the direction of the back surface 51b is blocked by oxygen.

Because of this, in the con. structure of FIG. 4, diffusion of hydrogen in the direction of the back surface 51b is blocked by [O,] in the MCZ wafer, so that the crystal defect layer 23 having the concentration lower than the impurity concentration C_{drift} of the n⁻-type drift layer 15 is formed. On the other hand, in the new structure 1 of the first and second preferred embodiment, because protons (H⁺) are introduced into the n-type second buffer layer 17, the crystal defect layer 23 is not formed. In addition, in the new structure 2 of the third preferred embodiment, because protons (H⁺) are introduced into the vicinity of the junction portion (X_{j,n1}) of the n-type first buffer layer 16, the crystal defect layer 23 is not formed.

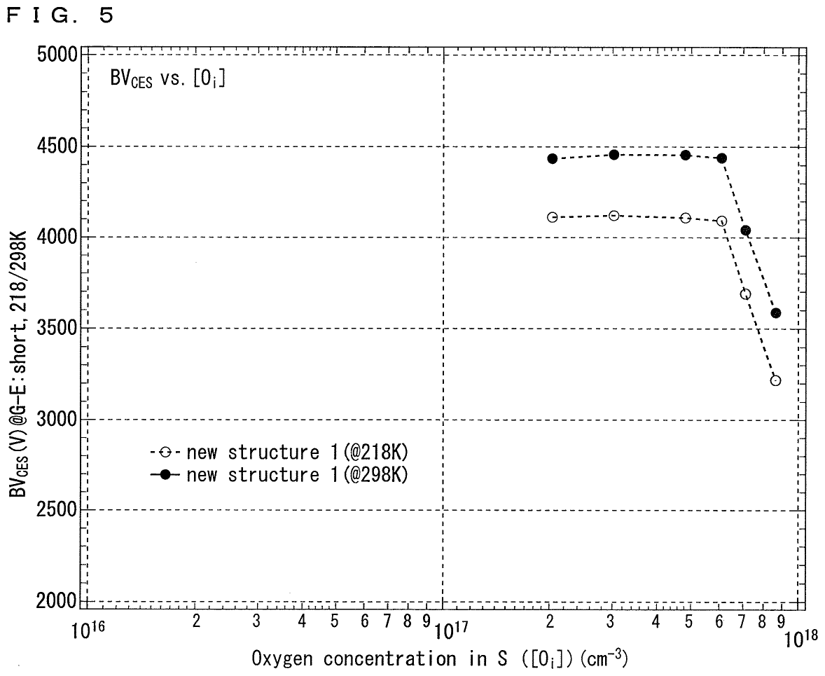

FIG. 5 is a view illustrating a relationship between an electrostatic breakdown voltage (BV_{ces}) and the oxygen concentration ([Oᵢ]) in the MCZ wafer for the IGBT (3.3 kV class, C_{drift}: 2.0×10¹³ cm⁻³) in which the n-type second buffer layer 17 has the impurity profile of the new structure 1. It can be seen From FIG. 5 that the electrostatic breakdown voltage (BV_{ces}) decreases when [Oᵢ] is higher than 6.0×10¹⁷ cm⁻³. [Oᵢ] higher than 6.0×10¹⁷ cm⁻³ is higher than the maximum [Oᵢ] in FIG. 3. Accordingly, the n-type second buffer layer 17 has the impurity profile of the new structure 1, so that it can be seen that the IGBT having the maximum [Oᵢ] lower than 6.0×10¹⁷ cm⁻³ has a sufficient off-state voltage (electrostatic breakdown voltage) retention capability even at a low temperature of 218K.

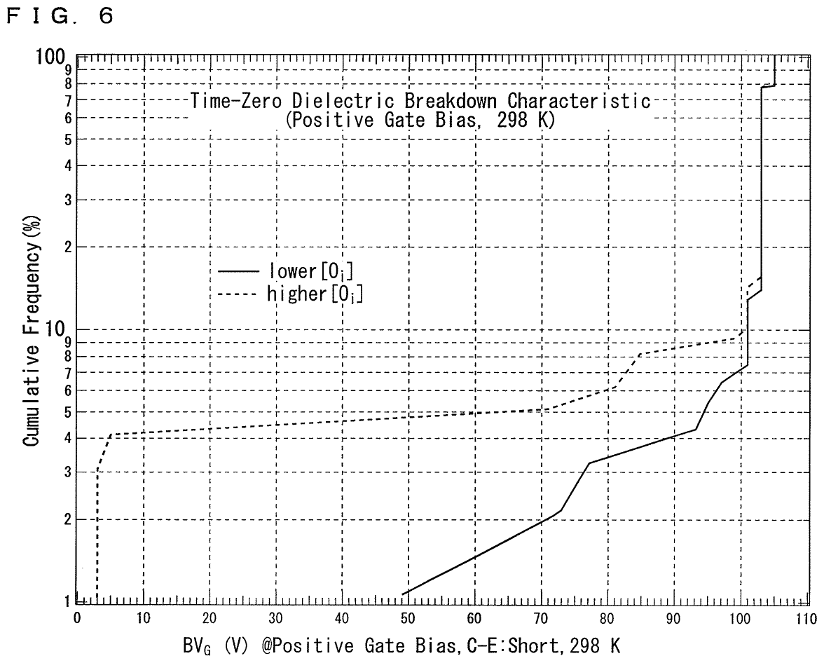

FIG. 6 is a view illustrating a relationship between a time-zero dielectric breakdown characteristic of the gate oxide film 13 and the oxygen concentration ([Oᵢ]) in the MCZ wafer for the IGBT in which the n-type second buffer layer 17 has the impurity profile of the new structure 1 (3.3 kV class, C_{drift}: 2.0×10¹³ cm⁻³, temperature 298 k). The lower [Oᵢ] in FIG. 6 corresponds to the maximum [Oᵢ] in FIG. 3, and the higher [Oᵢ] in FIG. 6 is higher than the maximum [Oᵢ] in FIG. 3. In the lower [Oᵢ], a probability that dielectric breakdown is generated even at a relatively high voltage (the probability corresponding to the cumulative frequency) is low.

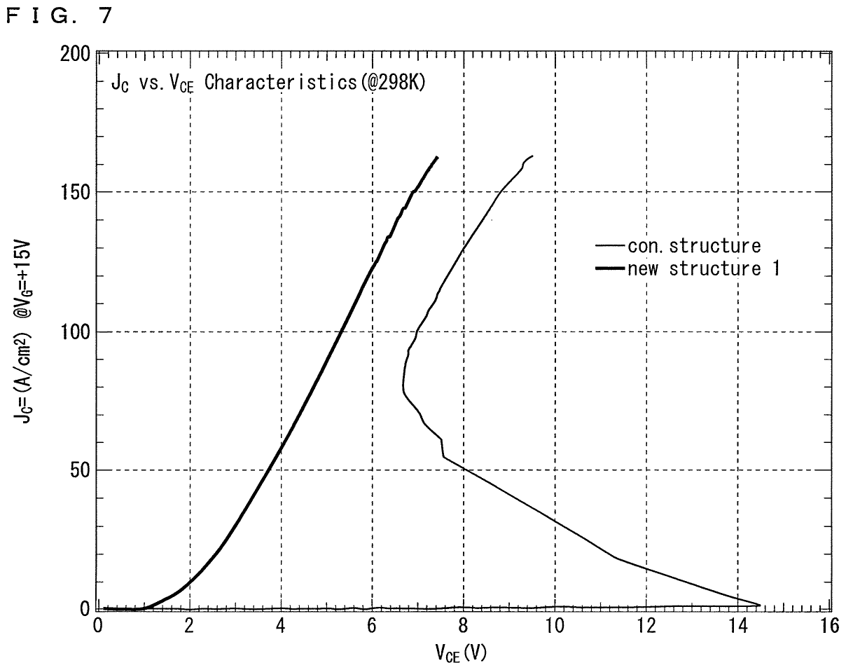

FIG. 7 is a view illustrating an output characteristic of the IGBT in which the n-type second buffer layer 17 has the impurity profile of the new structure 1 or the con. structure (6.5 kV class, C_{drift}: 5.0×10¹² cm⁻³). In the impurity profile of con. structure, the crystal defect layer 23 exists and a hole injection efficiency from the back surface 51b decreases at the initial time of the turn-on of the IGBT, a snap-back characteristic in which J_{C} does not monotonically increase with respect to V_{CE} is generated as illustrated in FIG. 7. For this reason, the normal on-operation of the IGBT cannot be implemented. On the other hand, in the impurity profile of the new structure 1, the crystal defect layer 23 that blocks hole injection from the back surface 51b of the IGBT does not exist, and J_{C} monotonically increases with respect to V_{CE} as illustrated in FIG. 7, so that the normal on-operation of the IGBT can be implemented.

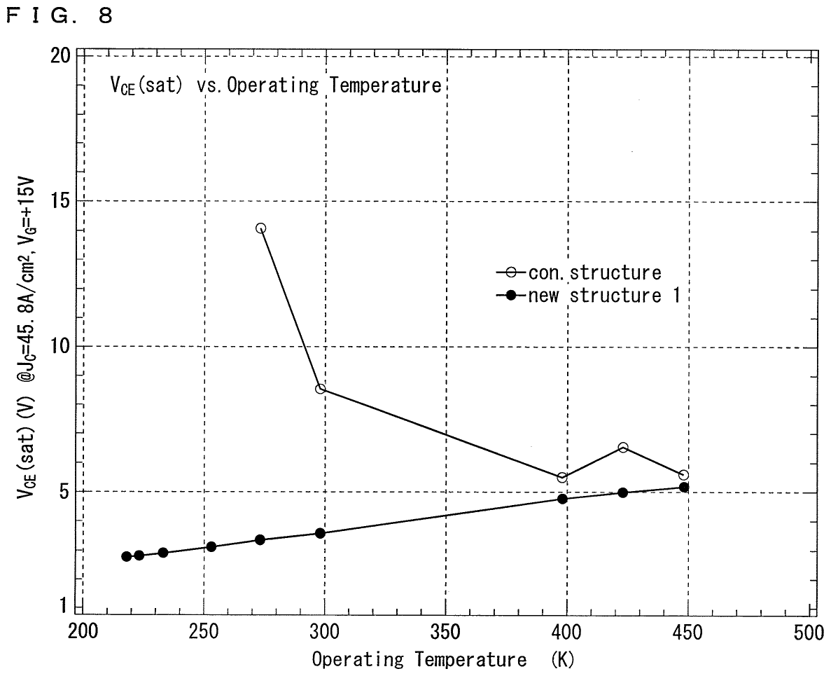

FIG. 8 is a view illustrating operating temperature dependence of the on-voltage (V_{CE}(sat)) for the IGBT (6.5 kV class, C_{drift}: 5.0×10¹² cm⁻³) in which the n-type second buffer layer 17 has the impurity profile of the new structure 1 or the con. structure. In the impurity profile of the con. structure, the crystal defect layer 23 exists and the snap-back characteristic is generated as illustrated in FIG. 7, so that V_{CE}(sat) tends to decrease to a specific temperature and increase from the specific temperature as illustrated in FIG. 8. On the other hand, in the impurity profile of the new structure 1, the dependency (that is, the rate of change) of V_{CE}(sat) on the temperature is maintained to be positive as illustrated in FIG. 8, which is effective in an operation aspect of the power module in which a large number of the semiconductor devices are incorporated in parallel.

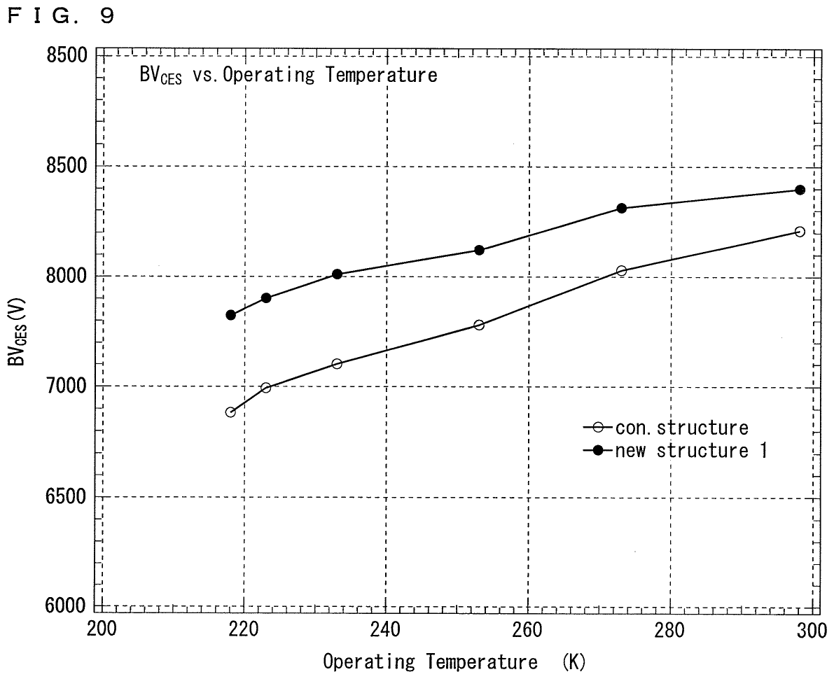

FIG. 9 is a view illustrating the operating temperature dependence of the withstand voltage (BV_{CES}) for the IGBT (6.5 kV class, C_{drift}: 5.0×10¹² cm⁻³) in which the n-type second buffer layer 17 has the impurity profile of the new structure 1 or the con. structure. As illustrated in FIG. 9, the withstand voltage retention capability in the off-state of the impurity profile of the new structure 1 is higher than the withstand voltage retention capability in the off-state of the impurity profile of the con. structure. The reason for this is considered to be that, in the impurity profile of the con. structure, a portion of the depletion layer extending from the main junction 12 on the side of the front surface 51a to the crystal defect layer 23 during the voltage retention of the semiconductor device serves as a leakage current generation source during the voltage retention, thereby causing the decrease in the voltage retention capability.

FIG. 10 is a view illustrating a relationship between maximum blocking energy (E_{SC}) and the on-voltage (V_{CE}(sat)) in the short-circuit state for the IGBT (6.5 kV class, C_{drift}: 5.0×10¹² cm⁻³) in which the n-type second buffer layer 17 has the impurity profile of the new structure 1 or the con. structure. As illustrated in FIG. 10, the maximum blocking energy (E_{SC}) in the short-circuit state of the impurity profile of the new structure 1 is higher than the maximum blocking energy (E_{SC}) in the short-circuit state of the impurity profile of the con. structure. In the impurity profile of the con. structure, because the crystal defect layer 23 exists, the carrier on the side of the back surface 51b of the IGBT in the short-circuit state disappears. By this behavior, the carrier concentration on the side of the back surface 51b of the IGBT in the short-circuit state decreases, the increase in the electric field intensity is caused, and the state inside the device becomes unbalanced. For this reason, in the IGBT having the impurity profile of the con. structure, it is considered that the blocking capability of the short-circuit state is reduced. On the other hand, in the IGBT having the impurity profile of the new structure 1, because the crystal defect layer 23 does not exist, it is considered that the breakdown resistance during the dynamic operation is improved.

FIG. 11 is a view illustrating a trade-off characteristic between a switching loss (E_{REC}) and an on-voltage (V_{F}) for the diode (b) (6.5 kV class, C_{drift}: 5.0×10¹² cm⁻³) in which the n-type second buffer layer 17 has the impurity profile of the new structure 1 or the con. structure. The diode having the impurity profile of the new structure 1 has a better waveform during recovery during the turn-off operation than the diode having the impurity profile of the con. structure. As a result, as illustrated in FIG. 11, the diode having the impurity profile of the new structure 1 can lower the switching loss (E_{REC}) at the same on-voltage as compared with the diode having the impurity profile of the con. structure. For this reason, in the diode having the impurity profile of the new structure 1, the trade-off characteristic between E_{REC} and V_{F} is improved.

FIG. 12 is a view illustrating a relationship between the maximum cutoff power density at turn-off and the maximum switching speed (dj/dt) at turn-off for the diode (b) (6.5 kV class, C_{drift}: 5.0×10¹² cm⁻³) in which the n-type second buffer layer 17 has the impurity profile of the new structure 1 or the con. structure. As illustrated in FIG. 12, the diode having the impurity profile of the new structure 1 can cut off higher power density at the same switching speed (dj/dt) than the diode having the impurity profile of the con. structure.

### Summary of First Preferred Embodiment

According to the semiconductor device (the IGBT, the diode (a), or the diode (b)) of the first preferred embodiment as described above, the maximum [Oᵢ]=9.40×10¹⁶×ln(C_{drift})−2.27×10¹⁸ is satisfied in the case where the maximum value of the oxygen concentration of the semiconductor substrate 51 calculated using the conversion factor of Old ASTM is maximum [Oᵢ] and where the impurity concentration of the n⁻-type drift layer is C_{drift}. According to such the configuration, for example, the normal on-operation and the improvement in the breakdown resistance during the dynamic operation while having the sufficient withstand voltage retention capability in the off-state can be implemented. That is, the withstand voltage characteristic and the switching characteristic can be stabilized.

### Second Preferred Embodiment

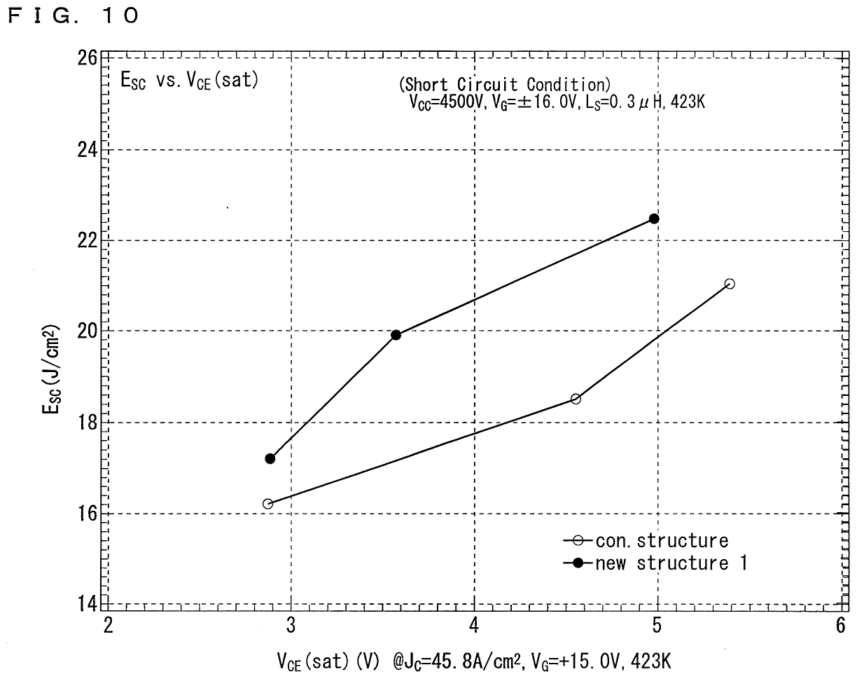

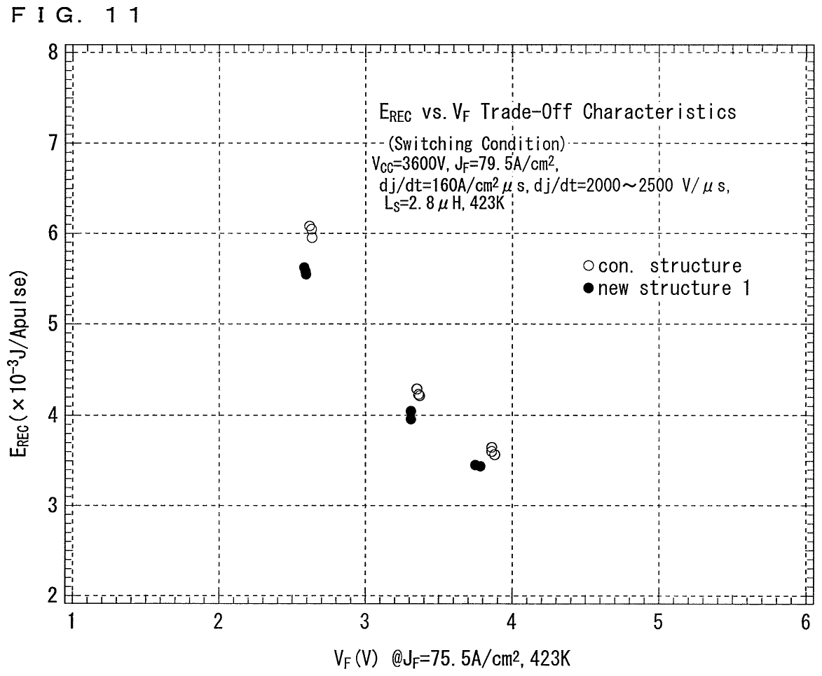

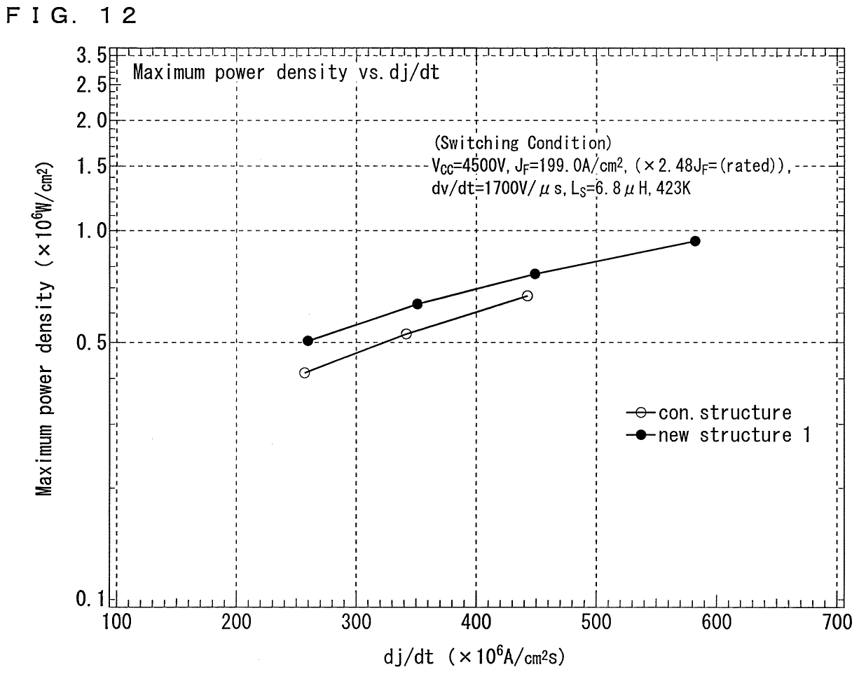

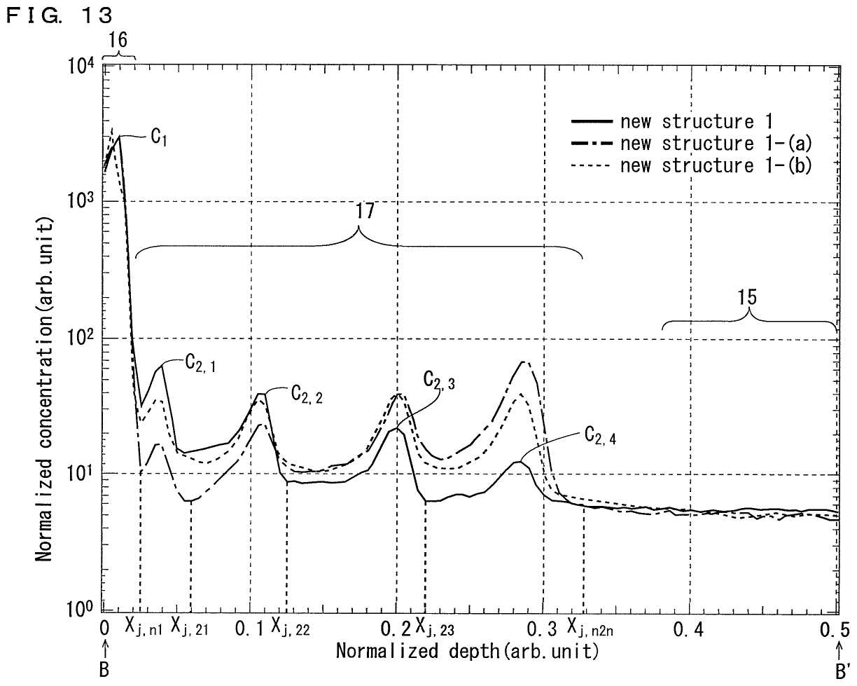

A sectional configuration of a semiconductor device according to a second preferred embodiment is similar to the sectional configuration (sectional configuration in FIG. 2) of the semiconductor device according to the first preferred embodiment. FIG. 13 is a view illustrating a measurement result of the impurity profile in the depth direction taken along line B-B′ in FIG. 2 according to the second preferred embodiment.

In the semiconductor device according to the second preferred embodiment, the maximum [Oᵢ] satisfies the formula (1), and the n-type second buffer layer 17 has the impurity profile of the new structure 1 in FIG. 4. For this reason, the n-type second buffer layer 17 includes the second-1 buffer layer to the second-n buffer layer (where n≥2). The second-1 buffer layer to the second-n buffer layer are provided in order from the n-type first buffer layer 16 toward the n⁻-type drift layer 15, and each have C_{2,1} to C_{2,n} as a peak value of the n-type impurity concentration.

That is, the second-1 buffer layer to the second-n buffer layer are sequentially provided in a direction from the junction portion (X_{j,n1}) between the n-type first buffer layer 16 and the n-type second buffer layer 17 toward the junction portion (X_{j,n2n}) between the n-type second buffer layer 17 and the n⁻-type drift layer 15. In the second preferred embodiment, C_{2,n}< . . . <C_{2,2}<C_{2,1} are satisfied.

In FIG. 13, the impurity profile is illustrated not only for the new structure 1 but also for a new structure 1-(a) and a new structure 1-(b) compared with the new structure 1. In the impurity profile of the new structure 1-(a), the relationship between the peak values is reversed in the impurity profile of the new structure 1, and C_{2,1}<C_{2,2}< . . . <C_{2,n} is satisfied. In the impurity profile of the new structure 1-(b), the peak values are almost the same in the impurity profile of the new structure 1, and C_{2,n}≈ . . . ≈C_{2,2}≈ . . . C_{2,1} are satisfied. In any of the three impurity profiles (the new structure 1, the new structure 1-(a), the new structure 1-(b)), a total dose amount, which is the total dose amount at the time of ion implantation for forming the second-1 buffer layer to the second-n buffer layer, is the same.

FIG. 14 is a view illustrating a device characteristic of the diodes (b) (1200-V class) having any of the three impurity profiles illustrated in FIG. 13. The diode having the impurity profile of the new structure 1 has the lower on-voltage (V_{F}), the lower leakage current (J_{R}) at 1200-V retention, and a wider safe operating area (SOA) in the dynamic state than the diode having the impurity profile of the new structure 1-(a) or the new structure 1-(b).

In the diode having the impurity profile of the new structure 1, because the extension of the depletion layer reaching the n-type second buffer layer 17 from the main junction 12 is gentle during the dynamic operation, the carrier plasma layer tends to remain in the region of the back surface 51b. The carrier plasma layer is a layer formed by conductivity modulation (modulation) generated in a portion of the n⁻-type drift layer 15 into which electrons and holes are injected when the semiconductor device is in the on-state, and is a neutral layer in which the electron concentration and the hole concentration are approximately the same. The behavior that the carrier plasma layer remains can be defined as an action of controlling the interaction between the carrier plasma layer and the electric field intensity during the dynamic operation of the semiconductor device (the IGBT, the diode (a), the diode (b)).

Due to the above behavior, in the diode having the impurity profile of the new structure 1, the maximum voltage (V_{snap-off}) in a V_{AK} waveform during the recovery operation indicating the SOA in a snappy mode can be made lower than the rated voltage (1200 V). For this reason, the prevention of the breakage and the improvement of controllability during the dynamic operation can be implemented.

In addition, due to the above behavior, the maximum cutoff current density (J_{A}(break)) during the recovery operation, which indicates the SOA of the high power supply voltage (V_{CC}) and the high current mode, increases in the diode having the impurity profile of the new structure 1, so that the SOA in the dynamic state can be expanded.

FIG. 15 is a view illustrating a relationship between diode performance and the maximum peak value C₂ of the diode in the n-type second buffer layer 17 for the diode (b) (1200-V class) in which the n-type second buffer layer 17 has the impurity profile of the new structure 1. In FIG. 15, the performance of the diode includes the withstand voltage (BV_{RRM}) and the dynamic SOA, and the maximum peak value C₂ corresponds to C_{2,1} of the second-1 buffer layer. The safe operating temperature on the vertical axis in FIG. 15 is the minimum operating temperature that can be cut off in the snappy mode of the diode.

A range of a physical quantity on the horizontal axis in FIG. 15 (that is, the range of the maximum peak value C₂ of the n-type second buffer layer 17) is preferably a range in which the physical quantity on the vertical axis does not depend on the physical quantity on the horizontal axis (a range less than or equal to 1.0×10¹⁵ cm⁻³ in FIG. 15). Accordingly, in the second preferred embodiment, the following formula (4) is satisfied, so that the dynamic SOA can be guaranteed while the sufficient withstand voltage retention capability of the diode in the off-state is maintained.

C_{drift}<C₂≤1.0×10¹⁵cm⁻³ (4)

FIG. 16 is a view illustrating a relationship between diode performance (the withstand voltage (BV_{RRM}) and a safe operating temperature in the snappy mode) and C₂/C₁ for the diode (b) (6.5 kV class) in which the n-type second buffer layer 17 has the impurity profile of the new structure 1. C₂/C₁ is a ratio of the maximum peak value C₂ of the n-type impurity concentration in the n-type second buffer layer 17 to the maximum peak value C₁ of the n-type impurity concentration in the n-type first buffer layer 16.

The range of the physical quantity on the horizontal axis in FIG. 16 (that is, the range of C₂/C₁) is preferably the range in which the physical quantity on the vertical axis does not depend on the physical quantity on the horizontal axis (in FIG. 16, the range of 1.0×10⁻⁴ cm⁻³ to 1.0×10⁻¹ cm⁻³). Accordingly, in the second preferred embodiment, the following formula (5) is satisfied, so that the dynamic SOA can be guaranteed while the sufficient withstand voltage retention capability of the diode in the off-state is maintained.

1.0×10⁻⁴≤C₂/C₁≤1.0×10⁻¹ (5)

### Third Preferred Embodiment

A sectional configuration of a semiconductor device according to a third preferred embodiment is similar to the sectional configuration (FIG. 2) of the semiconductor device according to the first preferred embodiment. FIG. 17 is a view illustrating a measurement result of the impurity profile in the depth direction taken along line B-B′ in FIG. 2 according to the third preferred embodiment.

In the semiconductor device according to the third preferred embodiment, the maximum [Oᵢ] satisfies the formula (1), and the n-type second buffer layer 17 has the impurity profile of the new structure 2 in FIG. 4. For this reason, the n-type second buffer layer 17 is a single layer having a single peak.

In FIG. 17, the impurity profiles are illustrated not only for the new structure 1 and the new structure 2 but also for the new structure 2-(a) and the new structure 2-(b) compared with the new structure 2. X₁ is the depth of the peak of the n-type impurity concentration in the n-type first buffer layer 16 from the back surface 51b, and X₂ is the depth of the peak of the n-type impurity concentration in the n-type second buffer layer 17 from the back surface 51b. In the impurity profile of the new structure 2-(a), the depth X₂ of the peak of the n-type second buffer layer 17 is deeper than the impurity profile of the new structure 2. In the impurity profile of the new structure 2-(b), the depth X₂ of the peak of the n-type second buffer layer 17 is deeper than the impurity profile of the new structure 2-(a).

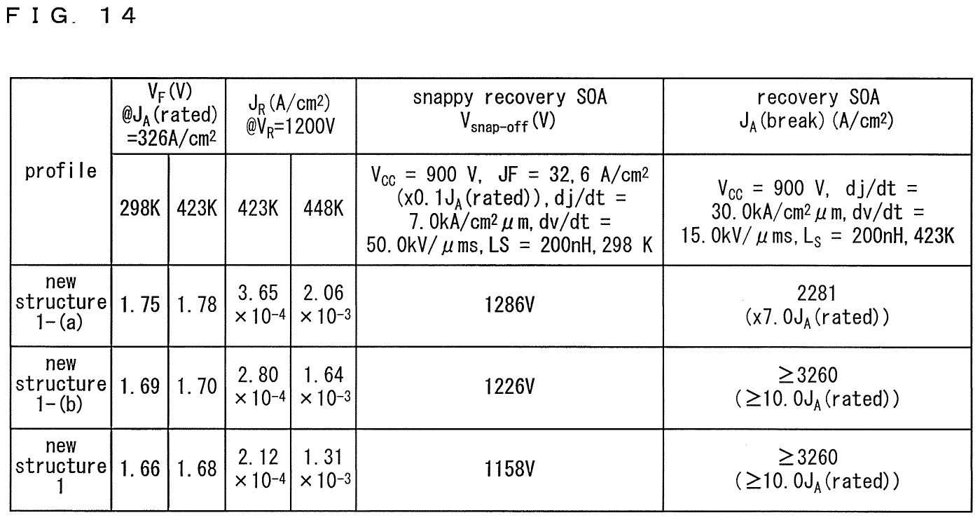

FIG. 18 is a view illustrating a relationship between the maximum blocking energy (E_{SC}) and the power supply voltage (V_{CC}) in the short-circuit state for the IGBT (6.5 kV class) having any one of the four impurity profiles in FIG. 17. FIG. 19 is a view illustrating a simulation result of a device internal state (the carrier concentration and the electric field intensity) in the short-circuit state (V_{CC}=2000 V, 298K). The position of the left end of the horizontal axis in FIG. 19 corresponds to the position of the front surface 51a, and the position of the right end of the horizontal axis corresponds to the position of the back surface 51b.

As illustrated in FIG. 18, in the impurity profiles of the new structure 2-(a) and the new structure 2-(b), the E_{SC} decreases and the SOA of the short-circuit mode becomes narrow in the region where the V_{CC} is 1500 V to 3500 V. As indicated by a thin one-dot chain line in FIG. 19, in the impurity profiles of the new structure 2-(a) and the new structure 2-(b), the electric field intensity in the n-buffer layer of the back surface 51b of the IGBT increases to the same extent as the electric field intensity of the main junction 12 of the front surface 51a. As described above, in the impurity profiles of the new structure 2-(a) and the new structure 2-(b), because the inside of the device in the short-circuit state is unbalanced, the SOA in the short-circuit mode is considered to be narrowed. At this point, the state in which the inside of the device in the short-circuit state is unbalanced means a state in which the electric field intensity of the main junction 12 of the front surface 51a described later is higher than the electric field intensity in the n-buffer layer of the back surface 51b.

On the other hand, as illustrated in FIG. 18, in the impurity profiles of the new structure 1 and the new structure 2, the maximum blocking energy (E_{SC}) in the short-circuit state linearly increases as the power supply voltage (V_{CC}) increases. As illustrated in FIG. 19, in the impurity profiles of the new structure 1 and the new structure 2, the electric field intensity of the main junction 12 of the front surface 51a is higher than the electric field intensity in the n-buffer layer of the back surface 51b even in the short-circuit state, and the state of the electric field intensity distribution inside the device in the short-circuit state is not unbalanced, so that the SOA in the short-circuit mode is not narrowed.

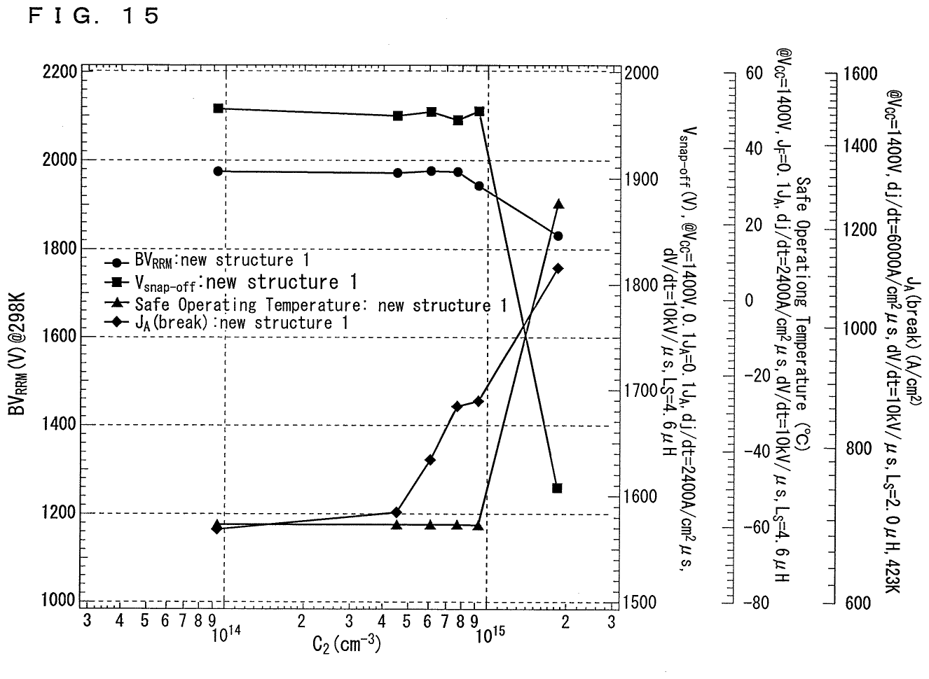

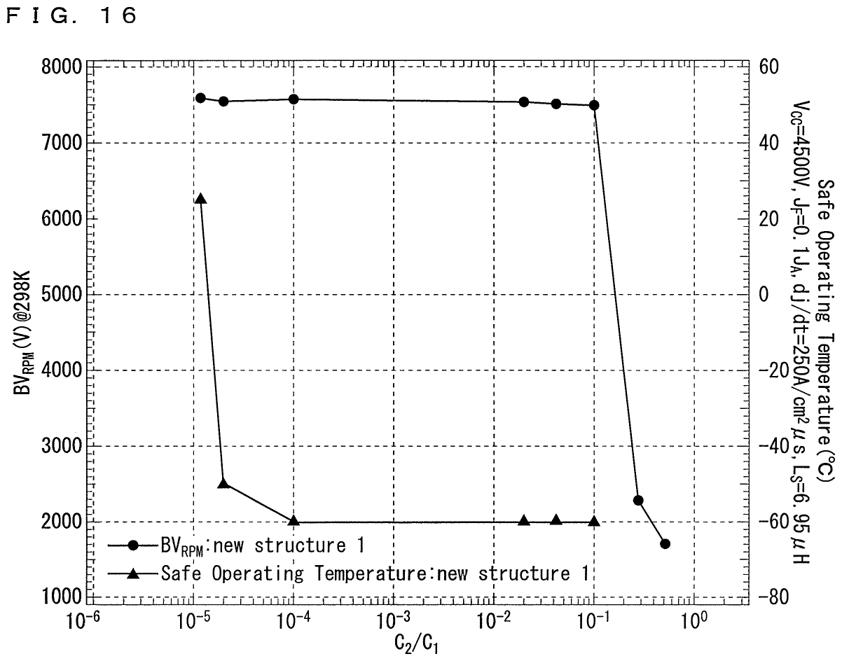

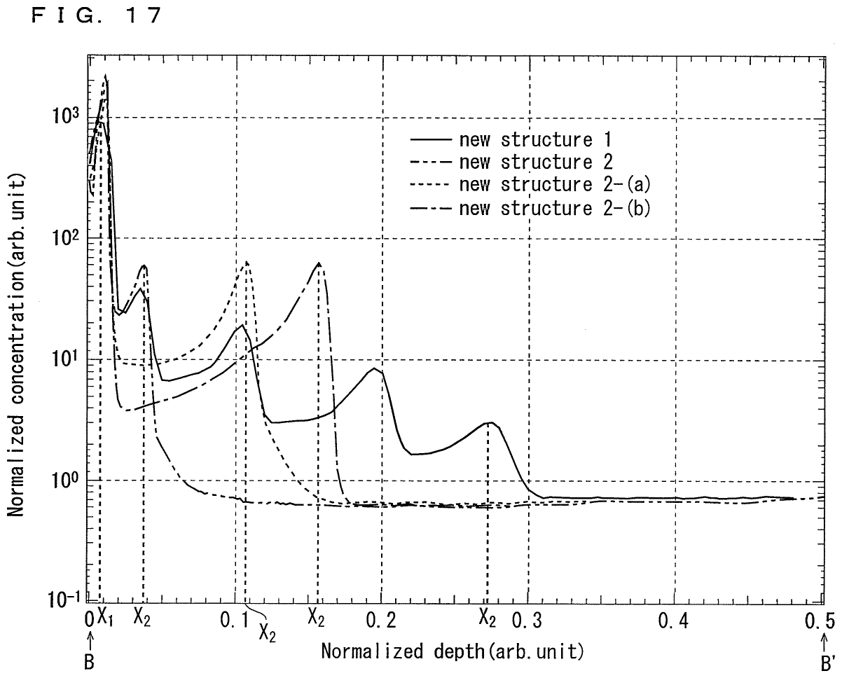

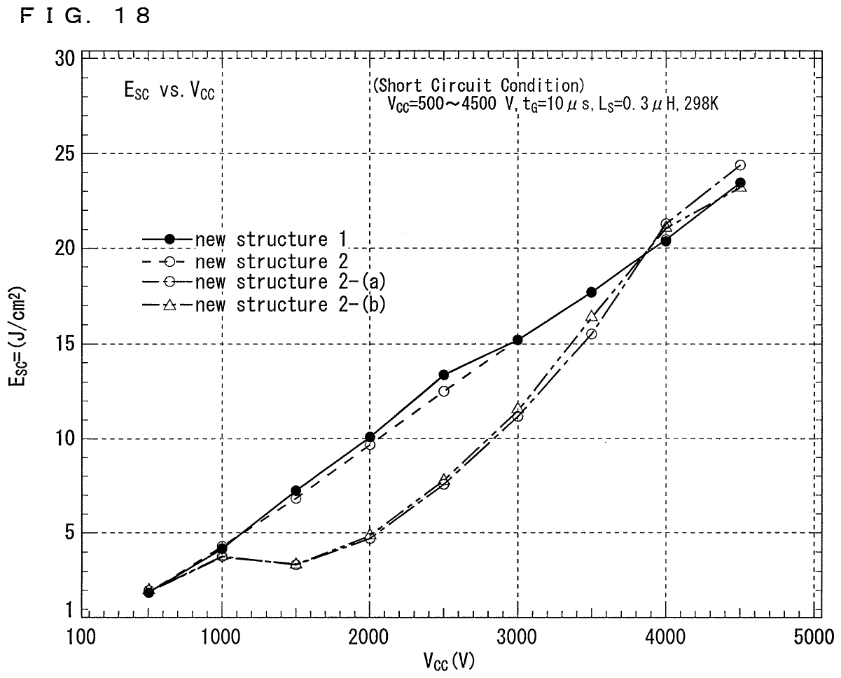

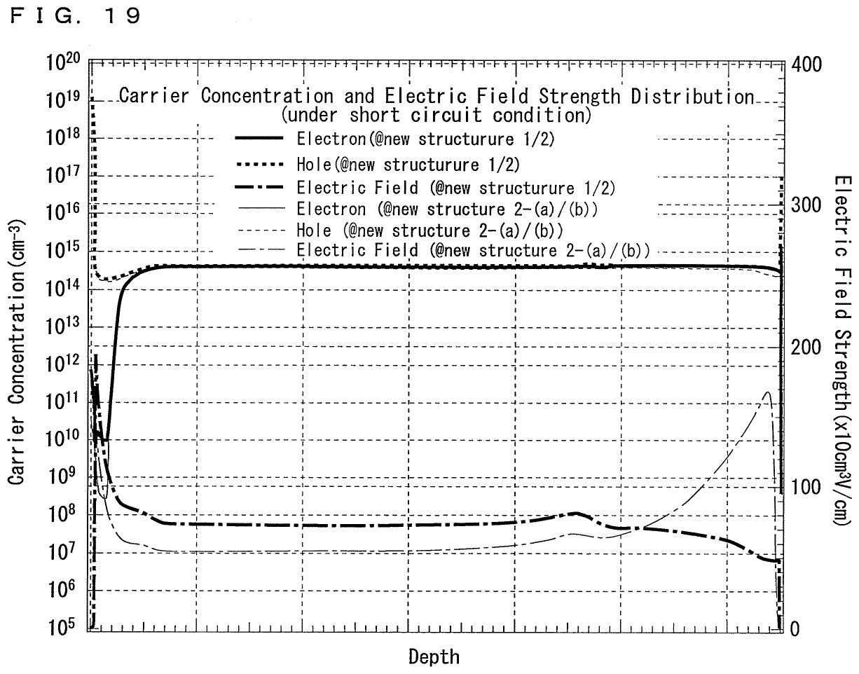

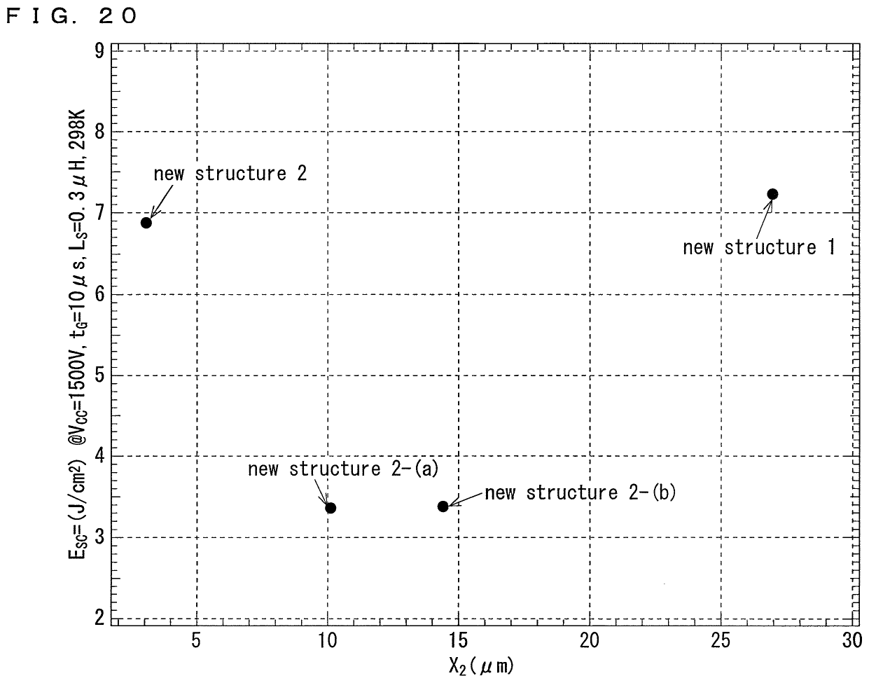

FIG. 20 is a view illustrating the relationship between the maximum blocking energy (E_{SC}) in the short-circuit state and the depth X₂ of the peak of the n-type impurity concentration in the n-type second buffer layer 17 for the IGBT (6.5 kV class) having one of the four impurity profiles in FIG. 17. The depth X₂ of the peak in the impurity profile of the new structure 1 of FIG. 20 is the depth of the peak (C_{2,n}) of the second-n buffer layer close to the n⁻-type drift layer 15. The semiconductor device (the semiconductor device having the new structure 2) according to the third preferred embodiment is configured such that the following formula (6) is satisfied in consideration of the relationship in FIG. 20. According to such the configuration, the dynamic SOA of the IGBT can be guaranteed.

X₁<X₂≤4.0 μm (6)

Assuming that the maximum peak value C₂ is the single peak value (C_{2,0}) in the impurity profile of the new structure 2, the relationship of the formula described in the second preferred embodiment may also be satisfied in the third preferred embodiment within the range where consistency is obtained.

### Fourth Preferred Embodiment

In a fourth preferred embodiment, a method of manufacturing the IGBT according to the first to third preferred embodiments will be described. FIGS. 21A to 23M are sectional views illustrating processes of the manufacturing method of the fourth preferred embodiment. In the manufacturing method according to the fourth preferred embodiment, the n-type first buffer layer 16 and the n-type second buffer layer 17 are formed as the diffusion layer in the semiconductor substrate 51 including the MCZ wafer, and one or at least two types of different acceleration energy and dose are used in the formation of the n-type second buffer layer 17.

First, as illustrated in FIG. 21A, the p-type base layer 9 and the n-type layer 11 are formed on the side of the front surface 51a of the n⁻-type drift layer 15 that is a part of the semiconductor substrate 51 by ion implantation and annealing. Subsequently, as illustrated in FIG. 21B, the n⁺-type emitter layer 7 is formed on the side of the front surface 51a of the p-type base layer 9 by ion implantation and annealing.

Then, as illustrated in FIG. 21C, the trench 24 penetrating the n⁺-type emitter layer 7 is formed by etching, and the inner wall of the trench 24 is cleaned, smoothed, and rounded by etching and oxidation. Subsequently, as illustrated in FIG. 21D, the gate oxide film 13 is formed on the inner wall of the trench 24, and the polysilicon film 14a doped with an n-type element (for example, arsenic or phosphorus) having the concentration of, for example, at least 1×10¹⁹ atoms/cm³ is formed on the gate oxide film 13. In FIG. 21D, the gate oxide film 13 and the polysilicon film 14a are also formed on the side of the back surface 51b of the semiconductor substrate 51.

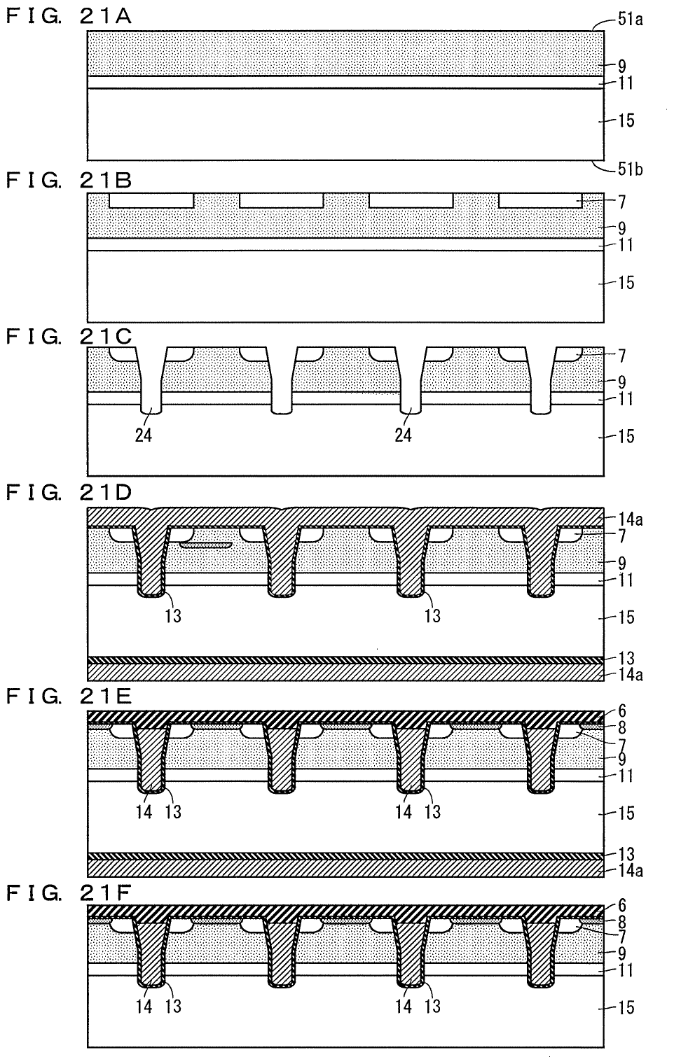

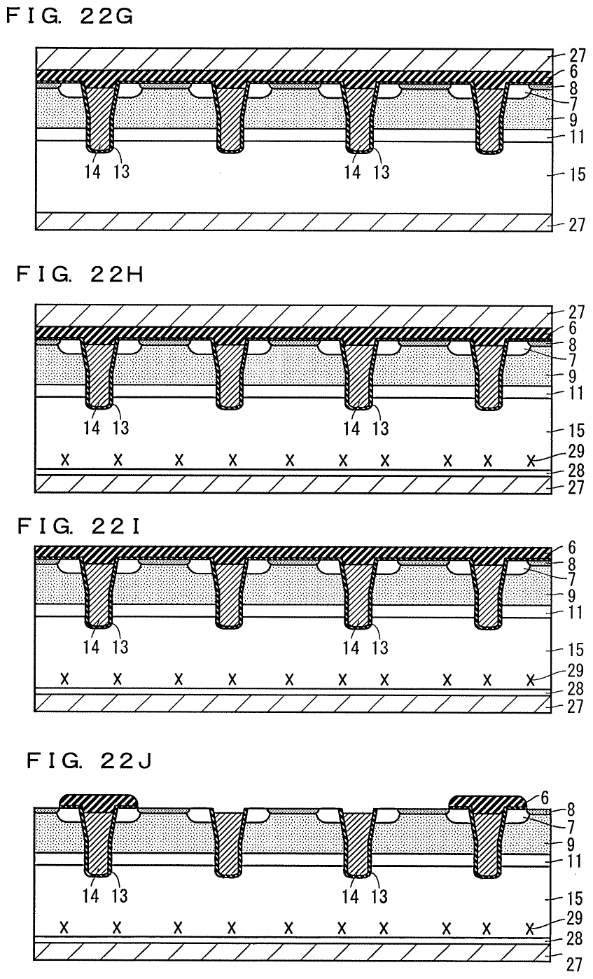

As described later, in the process of FIG. 22H through the processes of FIGS. 21E to 22G, a gettering layer including a polysilicon film 27, a high-concentration n⁺-type layer 28 on the side of the back surface 51b, and a high crystal defect density layer 29 is formed. The gettering layer recovers the carrier lifetime of the n⁻-type drift layer 15 such that the n⁻-type drift layer 15 has a value greater than or equal to the carrier lifetime calculated by the following formula (7).

τₜ≥1.5×10⁻⁵exp(5.4×10³×tₙ₋) (7)

tₙ₋[m] is the thickness of the n⁻-type drift layer 15, and is a device parameter corresponding to t_{device} in FIG. 2. rₜ[sec] is a carrier lifetime in the n⁻-type drift layer 15 in which the influence of the carrier lifetime on the on-voltage of the IGBT is eliminated.

The on-voltage of the semiconductor device (the IGBT, the diode (a), the diode (b)) depends on the carrier lifetime of the n⁻-type drift layer 15, and the formula (7) represents an index of the carrier lifetime required for minimizing the dependence. When rₜ satisfies the formula (7), the influence of the carrier life on the switching loss and the loss due to off can be prevented, the reduction of the loss due to off and the prevention of thermal runaway can be expected.

Hereinafter, the processes will be described in detail in order from FIG. 21E. First, as illustrated in FIG. 21E, the upper portion of the polysilicon film 14a on the side of the front surface 51a is removed to form the gate electrode 14, and the p⁺-type layer 8 and the interlayer film 6 are formed. Subsequently, as illustrated in FIG. 21F, in order to expose the back surface 51b of the semiconductor substrate 51, the gate oxide film 13 and the polysilicon film 14a on the side of the back surface 51b are removed by wet etching with a hydrofluoric acid or a mixed acid (for example, a mixture of a hydrofluoric acid, a nitric acid, and an acetic acid).

Then, as illustrated in FIG. 22G, the polysilicon film 27 doped with an n-type element is formed on the front surface 51a and the back surface 51b of the semiconductor substrate 51 by a low pressure CVD (LPCVD) method. The polysilicon film 27 is used as a source that forms the high concentration n⁺-type layer 28 and the high crystal defect density layer 29 in FIG. 22H. An element (atom) capable of diffusing into Si to form an n⁺-type layer, for example, phosphorus, arsenic, antimony, or the like is used as the n-type element (atom), and the polysilicon film 27 is doped with the element (atom) at a concentration of, for example, at least 1×10¹⁹ atoms/cm³. For example, the thickness of the polysilicon film 27 is greater than or equal to 500 nm.

Subsequently, the annealing is performed at 900° C. to 1000° C. and in a nitrogen atmosphere while the back surface 51b of the semiconductor substrate 51 is in direct contact with the polysilicon film 27 doped with a high-concentration impurity such as an n-type element. Then, the annealing is performed at a temperature lower than that of the previous annealing in the nitrogen atmosphere as 500° C. to 700° C. at an arbitrary temperature decreasing speed.

As illustrated in FIG. 22H, by this annealing, the high-concentration impurity in the polysilicon film 27 is diffused into the back surface 51b of the semiconductor substrate 51 in direct contact with the polysilicon film 27, and the high-concentration n⁺-type layer 28 is formed. For example, the high-concentration n⁺-type layer 28 has a surface impurity concentration of 1.0×10²⁰ atoms/cm³ to 1.0×10²² atoms/cm³, and the depth from the back surface 51b of 1.0 μm to 10 μm.

Along with the formation of the high-concentration n⁺-type layer 28, the high crystal defect density layer 29 into which a high density dislocation and a lattice defect are introduced is secondarily formed below the n⁻-type drift layer 15. In addition, when the annealing is performed while the polysilicon film 27 and the back surface 51b of the semiconductor substrate 51, having a different thermal expansion coefficient are in direct contact with each other, distortion is generated in the polysilicon film 27 and the surface layer portion of the high-concentration n⁺-type layer 28 that is a Si junction portion. Thus, the high-concentration n⁺-type layer 28 including the Si junction portion, the high crystal defect density layer 29, and the polysilicon film 27 become a gettering site. As a result, during the annealing, a heavy metal and a contaminating atom taken into the semiconductor substrate 51 are diffused in the crystal lattice and captured at the gettering site.

As the heavy metal and the contaminating atom are trapped in the gettering site, the carrier lifetime of the n⁻-type drift layer 15 reduced in the wafer process so far can be recovered similarly to the formula (7). That is, the carrier lifetime of the n⁻-type drift layer 15 can be made sufficiently long so as not to affect the electrical characteristics of the IGBTs of various withstand voltage classes and the carrier lifetime.

Since the front surface 51a of the semiconductor substrate 51 is not in direct contact with the polysilicon film 27 by the interlayer film 6, the gettering layer including the polysilicon film 27, the high concentration n⁺-type layer 28, and the high crystal defect density layer 29 is not formed on the side of the front surface 51a of the semiconductor substrate 51.

Instead of forming the high crystal defect density layer 29 using the polysilicon film 27, the high crystal defect density layer 29 may be formed on the semiconductor substrate 51 using laser annealing capable of rapid heating and rapid cooling and local annealing using laser having a wavelength of 500 nm to 1000 nm. For example, the power density of the laser annealing is greater than or equal to 4 J/cm². After the laser annealing, the annealing similar to the above is performed. That is, the annealing is performed at 900° C. to 1000° C. and in the nitrogen atmosphere, and then the annealing is performed at a temperature lower than that of the previous annealing in the nitrogen atmosphere as 500° C. to 700° C. at an arbitrary temperature decreasing speed. Even in this case, the heavy metal and the contaminating atom taken into the semiconductor substrate 51 diffuse in the crystal lattice and are captured by the gettering site, and as a result, the carrier lifetime of the n⁻-type drift layer 15 can be recovered.

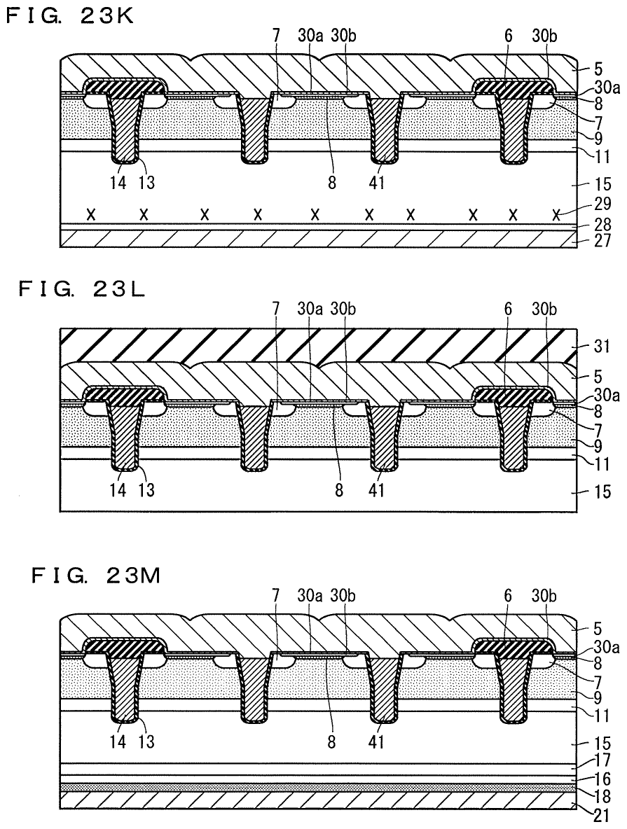

As described below, the gettering layer including the polysilicon film 27, the high concentration n⁺-type layer 28, and the high crystal defect density layer 29 is removed in the process of FIG. 23L before the process of FIG. 23M in which the n-type first buffer layer 16, the n-type second buffer layer 17, and the p-type collector layer 18 are formed.

As illustrated in FIG. 221, the polysilicon film 27 on the side of the front surface 51a is removed by etching. Subsequently, the interlayer film 6 is patterned as illustrated in FIG. 22J. In FIG. 22J, a part of the gate electrode 14 is exposed from the interlayer film 6, but all the gate electrodes 14 may be covered with the interlayer film 6.

As illustrated in FIG. 23K, the silicide layer 30a, the barrier metal layer 30b, and the first electrode 5 are formed in this order on the front surface 51a of the semiconductor substrate 51 and on the interlayer film 6. The gate electrode 14 that is exposed from the interlayer film 6 and connected to the first electrode 5 serves as a dummy electrode 41. That is, in the example of FIG. 23K, the trench electrode provided in the trench 24 includes the gate electrode 14 and the dummy electrode 41. By the processes up to FIG. 23K, the n-type semiconductor substrate 51 having the front surface 51a on which the first electrode 5 is provided and the back surface 51b opposite to the front surface 51a is formed.

As illustrated in FIG. 23L, after a protective film 31 is formed on the first electrode 5, the polysilicon film 27, the high concentration n⁺-type layer 28, and the high crystal defect density layer 29 are removed by polishing and wet etching, and the device thickness (t_{device}) in FIG. 2 is set to, for example, 40 μm to 700 μm. Even after the process of FIG. 23L, the carrier lifetime of the n⁻-type drift layer 15 satisfies the formula (7).

As illustrated in FIG. 23M, the n-type first buffer layer 16, the n-type second buffer layer 17, and the p-type collector layer 18 are formed on the back surface 51b, and the protective film 31 is removed. Thus, the vertical structure is formed on the side of the back surface 51b. On the front surface 51a on which the vertical structure is not formed, a trench structure of a metal oxide semiconductor field effect transistor (MOSFET) included in the IGBT already exists, and the first electrode 5, the interlayer film 6, and the like already exist. For this reason, at the time of forming the n-type first buffer layer 16, the n-type second buffer layer 17, and the p-type collector layer 18 constituting the vertical structure, the temperature of the first electrode 5 on the front surface 51a is significant to be lower than the melting point of the metal of the first electrode 5 (for example, the melting point of aluminum at 660° C.). In order to implement this, laser annealing using the laser having a wavelength at which the temperature gradient exists in the depth direction of the semiconductor substrate 51 and heat is hardly transferred to the front surface 51a, the annealing in a diffusion furnace at a low temperature lower than or equal to the metal melting point, or the like may be used.

Hereinafter, a method of manufacturing the IGBT described in the first and second preferred embodiments will be mainly described by performing the process of FIG. 23M after FIG. 23L. In the IGBT described in the first and second preferred embodiments, the n-type second buffer layer 17 includes the second-1 buffer layer to the second-n buffer layer that are provided in order from the n-type first buffer layer 16 toward the n⁻-type drift layer 15 and have C_{2,1} to C_{2,n} as the peak value of the n-type impurity concentration.

In such the method of manufacturing the IGBT, the control of point defects and composite defects in the second-1 buffer layer to the second-n buffer layer, and the formation of the second-1 buffer layer without interference between the n-type first buffer layer 16 and the second-1 buffer layer are significant. In order to implement this, as described below, the order of the formation of the n-type first buffer layer 16 and the n-type second buffer layer 17 and the setting of the peak position of acceleration energy during the ion implantation of the second-1 buffer layer to the second-n buffer layer are significant.

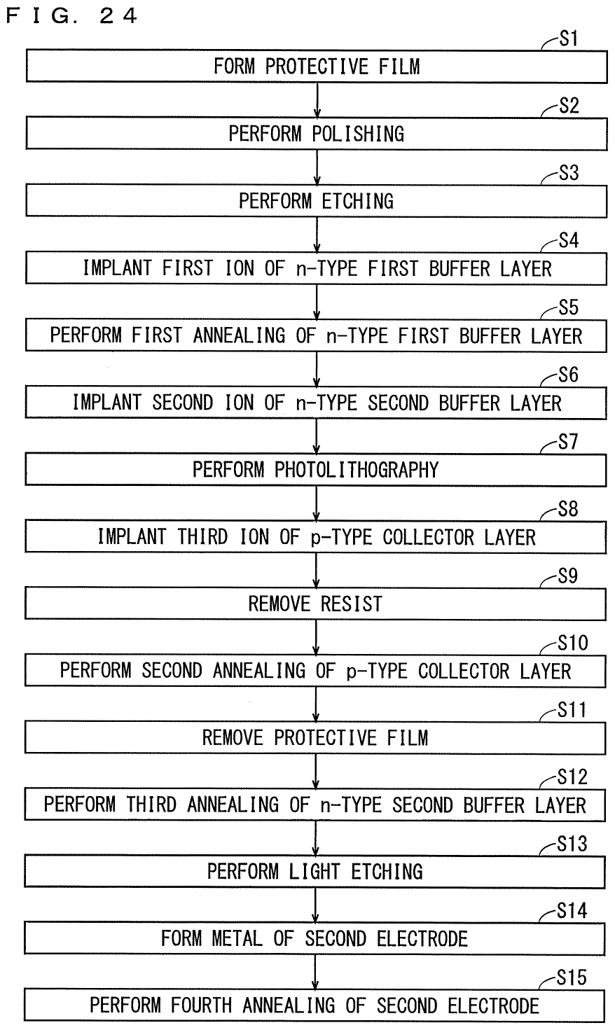

FIG. 24 is a flowchart illustrating a process of forming the structure on the side of the back surface 51b, namely, the processes of FIGS. 23L and 23M in the manufacturing method according to the fourth preferred embodiment. First, in step S1, as illustrated in FIG. 23L, the protective film 31 is formed on the first electrode 5. The polysilicon film 27, the high concentration n⁺-type layer 28, and the high crystal defect density layer 29 are removed by polishing in step S2 and etching in step S3, and the device thickness (t_{device}) in FIG. 2 is set to, for example, 40 μm to 700 μm.

In step S4, a first ion is implanted closer to the back surface 51b than the n⁻-type drift layer 15. In step S5, first annealing of the first ion is performed to form the n-type first buffer layer 16 as illustrated in FIG. 23M. For example, the first ion includes arsenic or phosphorus.

In step S6, a second ion is implanted between the n-type first buffer layer 16 and the n⁻-type drift layer. The second ion contains a proton (H⁺). Incidentally, a cyclotron may be used for proton implantation instead of general ion implantation.

In step S6, the protons (second ion) is introduced between the n-type first buffer layer 16 and the n⁻-type drift layer with at least one different acceleration energy and dose. For example, the proton (second ion) is implanted in the order of decreasing acceleration energy, and the dose amount of the proton implanted at the first acceleration energy is made lower than the dose amount of the proton implanted at the second acceleration energy lower than the first acceleration energy. Thus, the proton is injected from the proton that becomes the second-n buffer layer on the side of the n⁻-type drift layer 15 to the proton that becomes the second-1 buffer layer on the side of the n-type first buffer layer 16 in this order, and the dose amount of the proton increases. As a result, the n-type second buffer layer 17 including the second-1 buffer layer to the second-n buffer layer can be formed when the annealing of the proton (second ion) is performed.

The peak of the second-1 buffer layer in contact with the n-type first buffer layer 16 is set to be located on the side of the junction portion (X_{j,n2n}) between the n-type first buffer layer 16 and the second-1 buffer layer with respect to the junction portion (X_{j,n1}) between the n⁻-type drift layer 15 and the second-n buffer layer. Thus, the interference between the n-type first buffer layer 16 and the second-1 buffer layer is prevented, and the second-1 buffer layer can be accurately formed. When the IGBT according to the third preferred embodiment is manufactured, the proton (second ion) may be introduced at one type of different acceleration energy and dose amount.

In this manner, the n-type second buffer layer 17 can be formed when the proton (second ion) is annealed after step S6. However, the first annealing in step S5 of forming the n-type first buffer layer 16 and second annealing in step S10 of forming the p-type collector layer 18 described later are expected to be higher in temperature than third annealing for forming and activating the n-type second buffer layer 17. For this reason, when the annealing at a higher temperature than the third annealing is performed after the third annealing, an impurity profile of the HDs layer and types of point defects and composite defects in the n-type second buffer layer 17 introduced to form the n-type second buffer layer 17 are adversely affected. As a result, the carrier (electron or hole) in the on-state of the device is adversely affected.

For this reason, in the fourth preferred embodiment, the third annealing (step S12) that forms the n-type second buffer layer 17 is performed after the first annealing (step S5) that forms the n-type first buffer layer 16 and the second annealing (step S10) that forms the p-type collector layer 18.

When the proton (second ion) is introduced in step S6 and the third annealing is performed in step S12, the HDs layer is formed as in the following steps A1 to A4. First, in step A1, a hole (v) and an interstitial Si pair (I_{Si}) are generated by introducing protons into Si. In step A2, the interstitial Si pairs aggregate under a temperature of room temperature, and a W center (I_{Si3} cluster) that is the point defect is generated. In step A3, by the third annealing, the interstitial Si pairs re-aggregate to generate the X center (I_{Si4} cluster) that is the point defect. In step A4, hydrogen introduced by the proton reacts with the W center (I_{Si3} cluster) and the X center (I_{Si4} cluster) to generate donor type complex defects, thereby forming the HDs layer.

When the HDs layer is formed on the semiconductor substrate 51 using the MCZ wafer, the final n-type second buffer layer 17 is formed by adding the thermal donor phenomenon caused by the oxygen in Si. When the FZ wafer is used for the semiconductor substrate 51, the HDs layer directly becomes the n-type second buffer layer 17. As a result, the n-layer donated at the higher impurity concentration than the n⁻-type drift layer 15 contributes to the operation of the device as the n-type second buffer layer 17. Because the MCZ wafer is used in the fourth preferred embodiment, the improvement of the device performance is implemented by utilizing the composite defect formed in the n-type second buffer layer 17.

The composite defect formed in the n-type second buffer layer 17 also includes a defect serving as a lifetime killer that reduces the carrier lifetime. Accordingly, in the fourth preferred embodiment, as illustrated in FIG. 24, the second ion implantation (step S6) and the third annealing (step S12) of the n-type second buffer layer 17 are performed after the n-type first buffer layer 16 is formed (step S5). According to such the manufacturing method, the composite defect in the n-type second buffer layer 17 can be controlled, so that the removal the defect serving as the lifetime killer and the stabilization of the profile of the n-type second buffer layer 17 can be performed.

In step S7, photolithography is performed to form a patterned resist on the back surface 51b as a mask. In step S8, a third ion is implanted onto the side of the back surface 51b of the n-type first buffer layer 16 exposed from the mask. For example, the third ion contains boron. In step S9, the resist is removed. When the p-type collector layer 18 is not required to be partially formed, the processes of step S7 and step S9 may be deleted. In step S10, the second annealing of boron (third ion) is performed to form the semiconductor layer including the p-type collector layer 18. In the second annealing, for example, the same annealing as the first annealing process is performed. In step S11, the protective film 31 on the first electrode 5 is removed.

In step 512, the third annealing of the proton (second ion) is performed to form the n-type second buffer layer 17. As the third annealing that donates the n-type second buffer layer 17, the proton (second ion) is annealed at a temperature greater than or equal to 375° C. and less than or equal to 425° C. for a time greater than or equal to 90 minutes. In the third annealing, the annealing different from that in the first annealing process is performed.

In step S13, light etching is performed on the back surface 51b of the semiconductor substrate 51. In step 514, a metal film that becomes the second electrode 21 is formed on the back surface 51b of the semiconductor substrate 51 by sputtering. For example, the metal film is an AlSi film in which the added amount of Si is 1% to 3%. In step S15, fourth annealing that forms an alloy layer or a silicide layer between the back surface 51b of the semiconductor substrate 51 and the metal film is performed to form the second electrode 21. For example, the temperature of the fourth annealing is lower than that of the third annealing lower than 375° C.

As described above, the IGBTs according to the first to third preferred embodiments are completed. When the maximum value of the oxygen concentration of the semiconductor substrate 51 is the maximum [Oᵢ], the formula (1) is satisfied. In addition, with respect to the carrier lifetime, the following formula (8) is satisfied among the n⁻-type drift layer 15, the n-type first buffer layer 16, and the n-type second buffer layer 17.

τ₂<τ₁≤τₜ (8)

τ₂ is the carrier lifetime of the n-type second buffer layer 17, and τ₁ is the carrier lifetime of the n-type first buffer layer 16. τₜ is the carrier lifetime of the n⁻-type drift layer 15 without affecting the on-voltage of the IGBT (that is, the on-voltage of the gate electrode).

According to the method of manufacturing the semiconductor device according to the fourth preferred embodiment as described above, the IGBT according to the first to third preferred embodiments can be formed. In the fourth preferred embodiment, the n-type second buffer layer 17 that is formed of the MCZ wafer made of Si having the high oxygen concentration and includes the HDs layer by the third annealing of the proton (second ion) and to which the thermal donor phenomenon is applied can be formed. In the fourth preferred embodiment, the order of the formation of the n-type first buffer layer 16 and the n-type second buffer layer 17 and the setting of the peak position of the acceleration energy during the ion implantation of the second-1 buffer layer to the second-n buffer layer are adequately performed. For this reason, the point defects and composite defects in the second-1 buffer layer to the second-n buffer layer can be controlled, and the interference between the n-type first buffer layer 16 and the second-1 buffer layer can be prevented.

### Fifth Preferred Embodiment

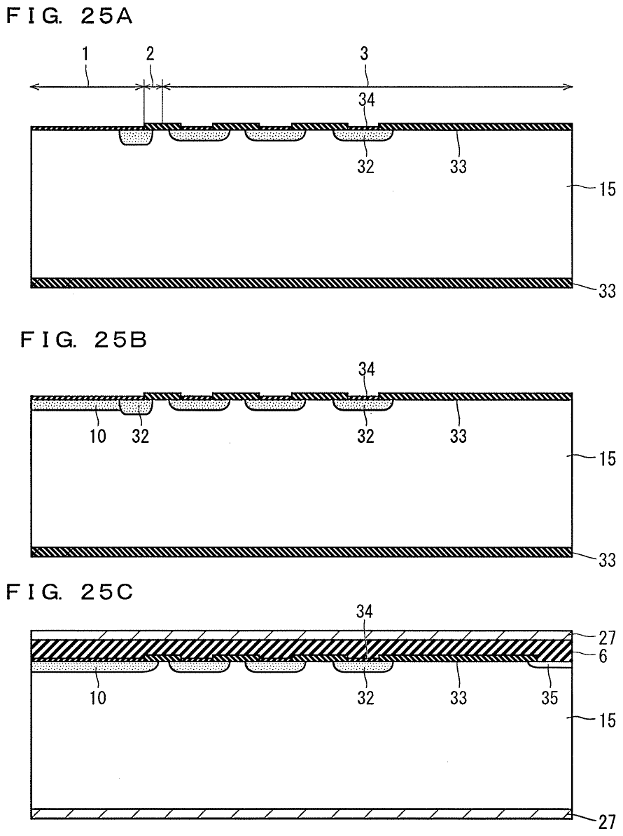

In a fifth preferred embodiment, a method of manufacturing the diode (a) and the diode (b) according to the first to third preferred embodiments will be described. FIGS. 25A to 271 are sectional views illustrating processes of the manufacturing method according to the fifth preferred embodiment, and specifically, are sectional views illustrating processes of the manufacturing method of the diode (b). Also in the fifth preferred embodiment, similarly to the fourth preferred embodiment, the n-type first buffer layer 16 and the n-type second buffer layer 17 are formed on the semiconductor substrate 51 including the MCZ wafer, and one or at least two types of different acceleration energies and doses are used for the formation of the n-type second buffer layer 17.

First, as illustrated in FIG. 25A, a patterned oxide film 33 is formed on the front surface 51a of the semiconductor substrate 51 by photoengraving and resist removal. Thereafter, a thin oxide film 34 is formed by reoxidation, and a p-type layer 32 is formed on the side of the front surface 51a of the n⁻-type drift layer 15 in the termination region 3 using ion implantation, photolithography, resist removal, and annealing. Subsequently, as illustrated in FIG. 25B, the p-type anode layer 10 is formed on the side of the front surface 51a of the n⁻-type drift layer 15 in the active region 1 by ion implantation, photolithography, resist removal, and annealing. Then, as illustrated in FIG. 25C, a part of the oxide film 33 in the termination region 3 is removed, and an n⁺-type layer 35 is formed on the front surface 51a using ion implantation, photolithography, resist removal, and annealing. Then, after the oxide-film interlayer film 6 is formed on the front surface 51a, the polysilicon film 27 described in the fourth preferred embodiment is formed on the side of the front surface 51a and the side of the back surface 51b.

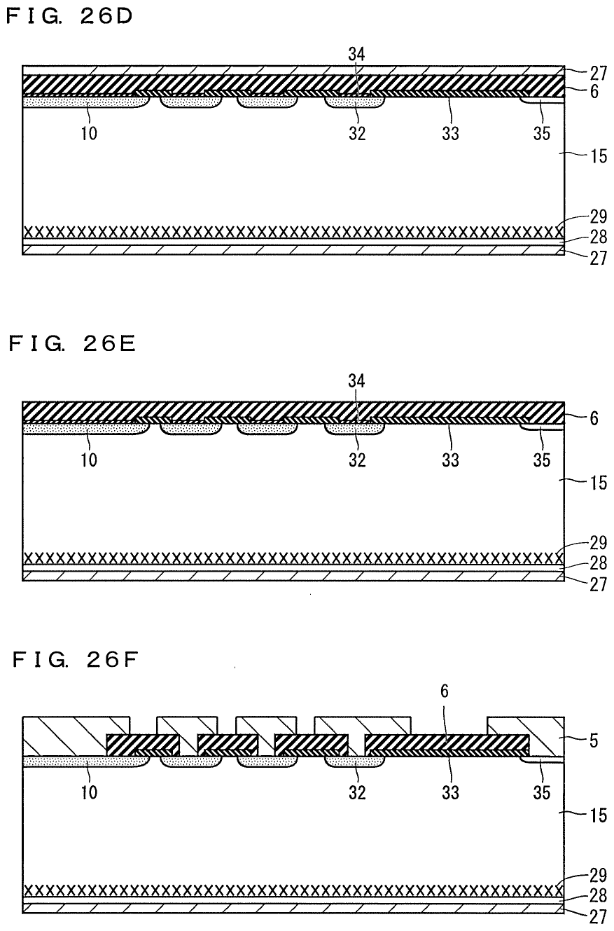

Subsequently, annealing is performed at 900° C. to 1000° C. and in the nitrogen atmosphere, and then annealing is performed at a temperature lower than that of the previous annealing in the nitrogen atmosphere as 500° C. to 700° C. at an arbitrary temperature decreasing speed. Thus, as illustrated in FIG. 26D, the gettering site including the high-concentration n⁺-type layer 28 including the Si junction portion, the high crystal defect density layer 29, and the polysilicon film 27 is formed on the side of the back surface 51b. As a result, similarly to the n⁻-type drift layer 15 according to the fourth preferred embodiment, the n⁻-type drift layer 15 according to the fifth preferred embodiment also recovers the carrier lifetime and satisfies the formula (7).

Then, as illustrated in FIG. 26E, the polysilicon film 27 on the side of the front surface 51a is removed by etching. Subsequently, as illustrated in FIG. 26F, the interlayer film 6 and the like are patterned to form the first electrode 5 on the exposed p-type anode layer 10, the p-type layer 32, and the n⁺-type layer 35 and on the interlayer film 6. Similarly to FIG. 23K, the silicide layer 30a and the barrier metal layer 30b may be provided.

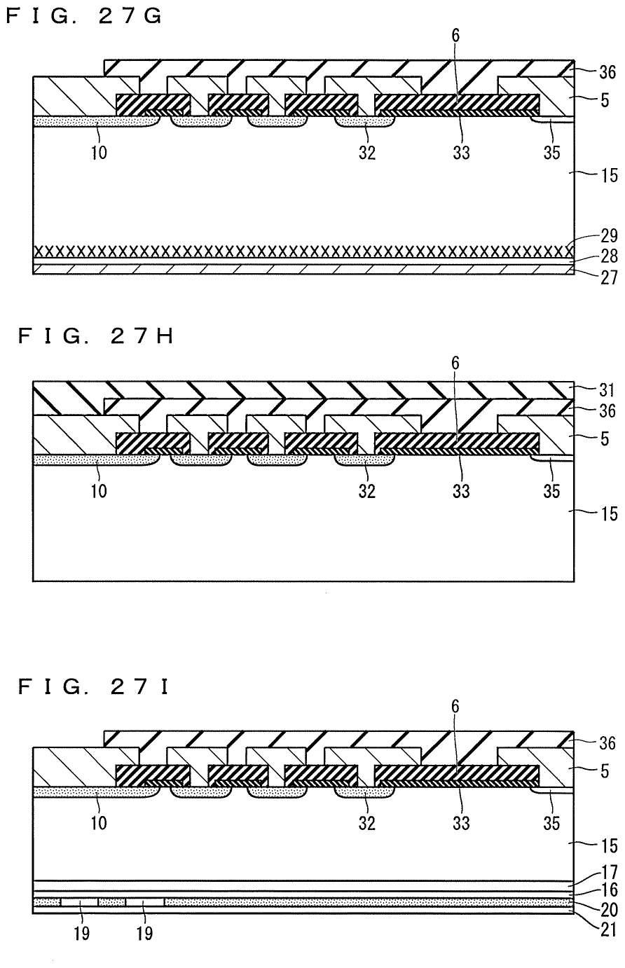

Subsequently, as illustrated in FIG. 27G, a passivation film 36 is formed on the first electrode 5. Then, as illustrated in FIG. 27H, after the protective film 31 is formed on the first electrode 5, the polysilicon film 27, the high concentration n⁺-type layer 28, and the high crystal defect density layer 29 are removed by polishing and wet etching. Then, as illustrated in FIG. 271, the n-type first buffer layer 16, the n-type second buffer layer 17, the n⁺-type cathode layer 19, and the p-type cathode layer 20 are formed on the back surface 51b, and the protective film 31 is removed.

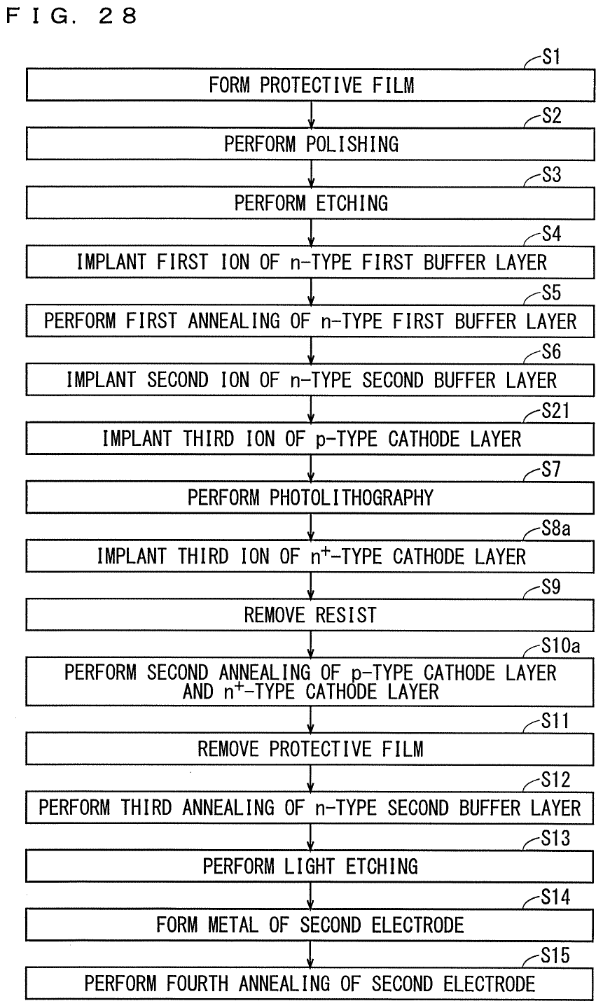

FIG. 28 is a flowchart illustrating the process of forming the structure on the side of the back surface 51b, namely, the processes of FIGS. 27H and 271 in the method of manufacturing the diode (b) according to the fifth preferred embodiment. The process of FIG. 28 is similar to the process in which step S21 is added to the process of FIG. 24 and steps S8, S10 are changed to steps S8a, S10a.

In step S21 between step S6 and step S7, the third ion containing, for example, boron is implanted onto the side of the back surface 51b of the n-type first buffer layer 16. In step S8a after step S7, the third ion containing, for example, arsenic or phosphorus is implanted onto the side of the back surface 51b of the n-type first buffer layer 16 exposed from the mask. The third ion in step 8a and the third ion in step S21 form the semiconductor layer connected to the second electrode 21, but the conductive type of the third ion in step 8a is different from the conductive type of the third ion in step S21. After step S9, in step S10a, the semiconductor layer including the n⁺-type cathode layer 19 and the p-type cathode layer 20 is formed by performing the second annealing of the third ion.

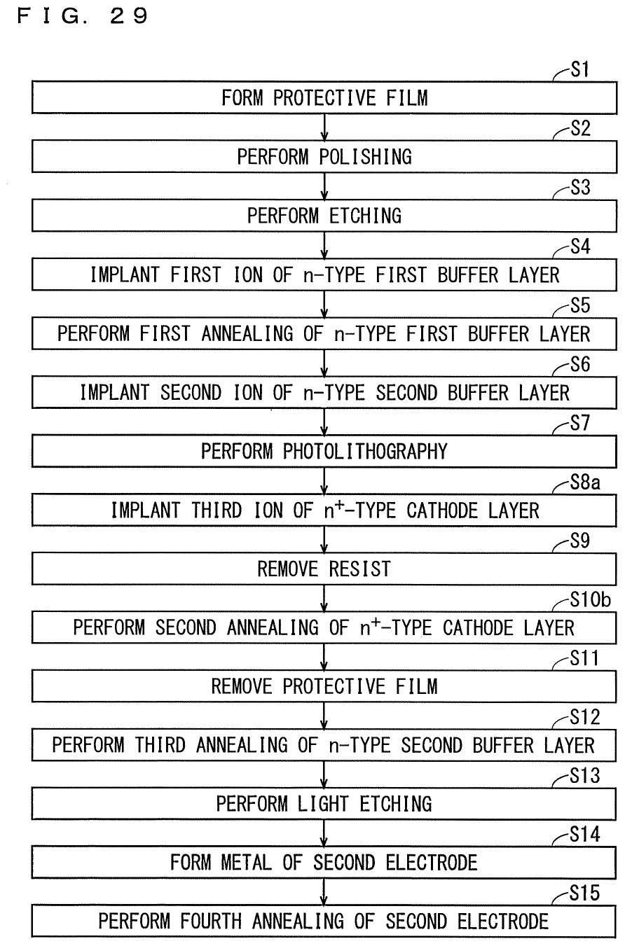

FIG. 29 is a flowchart illustrating a process of forming the structure on the side of the back surface 51b in the method of manufacturing the diode (a) according to the fifth preferred embodiment. The process of FIG. 29 is similar to the process in which step S21 is deleted from the process of FIG. 28 and step S10a is changed to step S10b. When the second annealing of the third ion is performed in step S10b, the semiconductor layer that does not include the p-type cathode layer 20 but includes the n⁺-type cathode layer 19 is formed. When the n⁺-type cathode layer 19 is not required to be partially formed, the processes of step S7 and step S9 may be deleted.

The diode (a) or the diode (b) according to the first to third preferred embodiments can be formed by the method of manufacturing the semiconductor device according to the fifth preferred embodiment as described above. In addition, in the fifth preferred embodiment, the n-type second buffer layer 17 that is formed of an MCZ wafer made of Si having the high oxygen concentration and includes the HDs layer by the third annealing of the proton (second ion) and to which the thermal donor phenomenon is applied can be formed. In the fifth preferred embodiment, the order of the formation of the n-type first buffer layer 16 and the n-type second buffer layer 17 and the setting of the peak position of the acceleration energy during the ion implantation of the second-1 buffer layer to the second-n buffer layer are adequately performed. For this reason, the point defects and composite defects in the second-1 buffer layer to the second-n buffer layer can be controlled, and the interference between the n-type first buffer layer 16 and the second-1 buffer layer can be prevented.

### Sixth Preferred Embodiment

In the semiconductor device according to the first to third preferred embodiments, the IGBT or the diode is provided in the active region 1 of the semiconductor substrate 51, but both the IGBT and the diode may be provided in the active region 1 of the same semiconductor substrate 51.

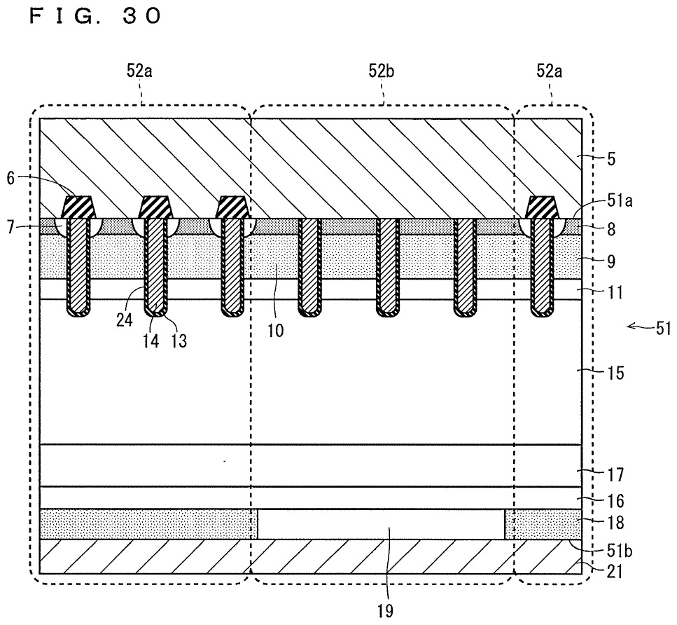

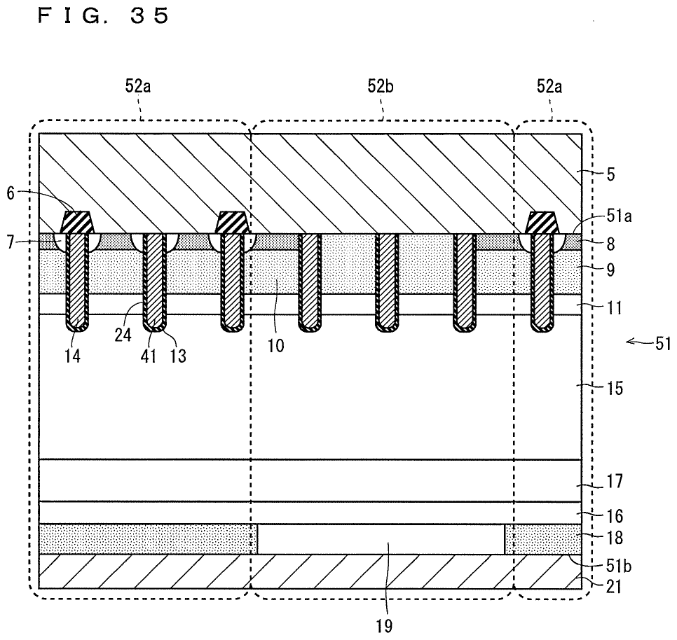

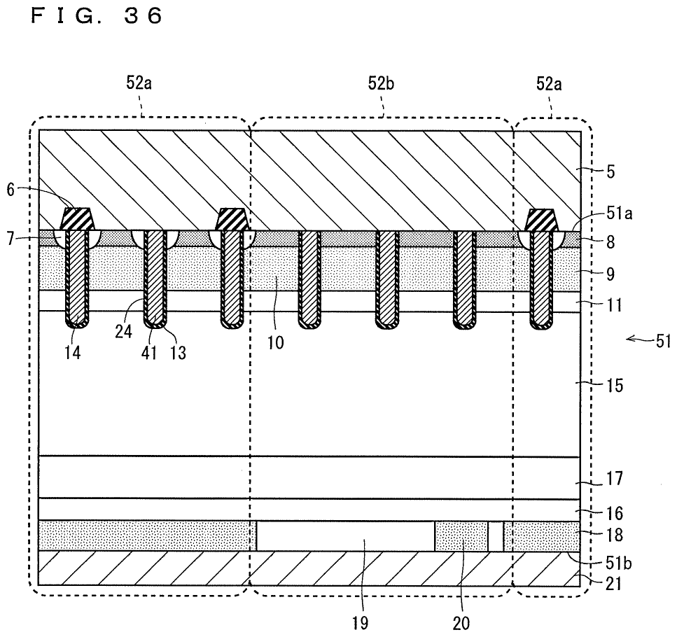

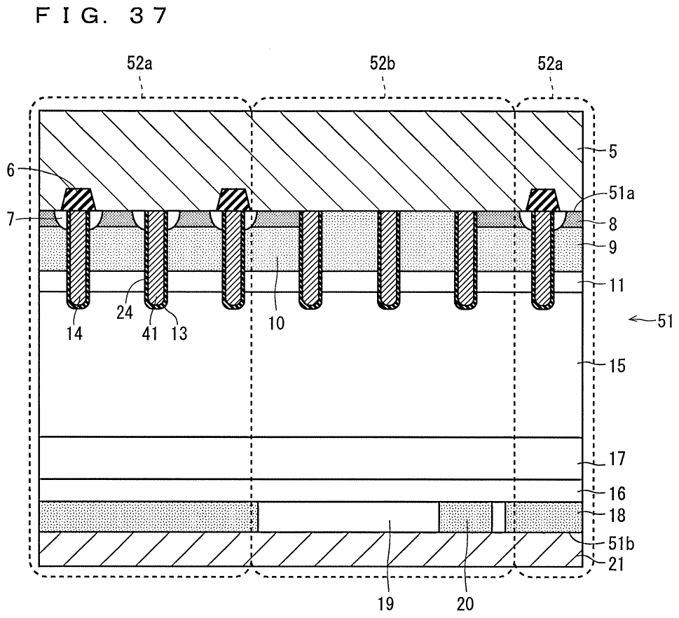

FIGS. 30 to 37 are sectional views illustrating a configuration of a semiconductor device according to a sixth preferred embodiment. The semiconductor device according to the sixth preferred embodiment is a reverse conducting-IGBT (RC-IGBT) that includes the IGBT and diode provided on the same semiconductor substrate 51 and has a trench gate structure. An IGBT region 52a functioning as the IGBT and a diode region 52b functioning as a diode are defined in the semiconductor substrate 51 of the RC-IGBT.

The same configuration as the IGBT according to the first to third preferred embodiments including the n-type first buffer layer 16, the n-type second buffer layer 17, and the p-type collector layer 18 is provided in the IGBT region 52a. In the diode region 52b, similarly to the diode (a) or the diode (b) according to the first to third preferred embodiments, the n-type first buffer layer 16 and the n-type second buffer layer 17, and both the n⁺-type cathode layer 19 and the p-type cathode layer 20, or the n⁺-type cathode layer 19 are provided.

The same configuration as that of the diode (a) according to the first to third preferred embodiments including the n⁺-type cathode layer 19 without including the p-type cathode layer 20 is provided in the diode region 52b of FIG. 30. The p⁺-type layer 8 having a p-type impurity concentration higher than that of the p-type anode layer 10 is provided between the first electrode 5 and the p-type anode layer 10.

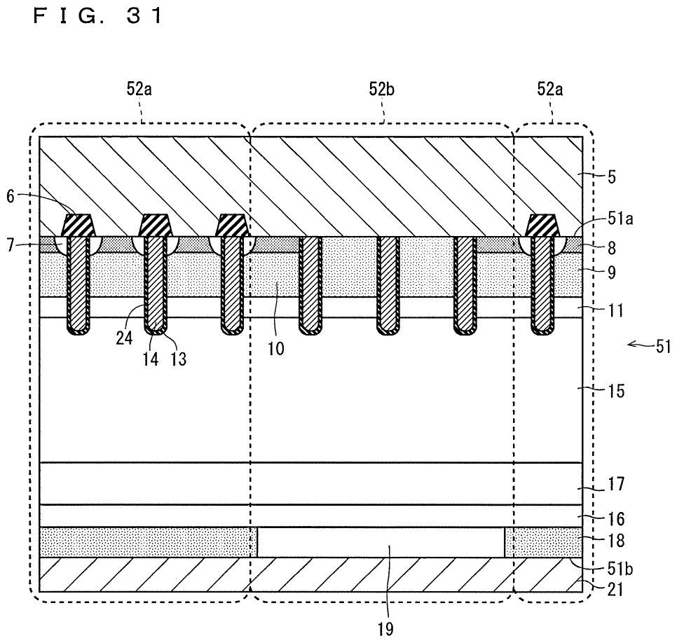

The configuration of FIG. 31 is similar to the configuration in which the p⁺-type layer 8 is removed from the configuration of FIG. 30, and the p-type anode layer 10 is in contact with the first electrode 5. According to the configuration of FIG. 31, the hole injection efficiency from the p-type anode layer 10 can be lowered when the diode is in the on-state as compared with the configuration of FIG. 30.

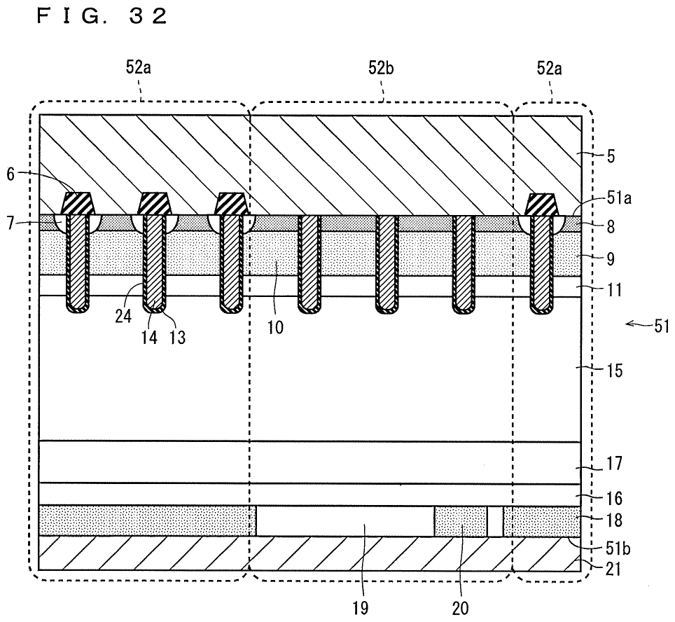

The same configuration as that of the diode (b) according to the first to third preferred embodiments including both the n⁺-type cathode layer 19 and the p-type cathode layer 20 is provided in the diode region 52b of FIG. 32. The p⁺-type layer 8 having a p-type impurity concentration higher than that of the p-type anode layer 10 is provided between the first electrode 5 and the p-type anode layer 10.

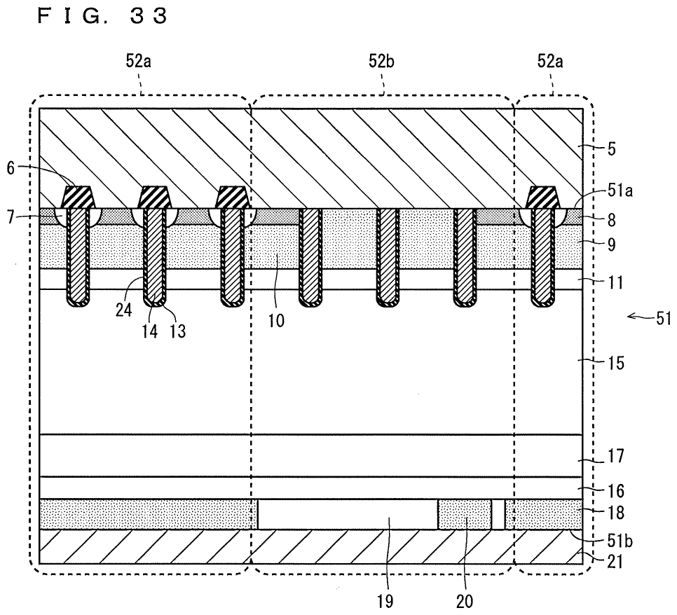

The configuration of FIG. 33 is similar to the configuration in which the p⁺-type layer 8 is removed from the configuration of FIG. 32, and the p-type anode layer 10 is in contact with the first electrode 5. According to the configuration of FIG. 33, the hole injection efficiency from the p-type anode layer 10 can be lowered when the diode is in the on-state as compared with the configuration of FIG. 32. In addition, according to the configurations of FIGS. 32 and 33, the p-type cathode layer 20 can lower the electron injection efficiency from the back surface 51b when the diode is in the on-state as compared with the configurations of FIGS. 30 and 31.

The RC-IGBT in FIGS. 31 to 33 can prevent the hole injection efficiency from the p-type base layer 9 or the electron injection efficiency from the back surface 51b when the diode is in the on-state as compared with the RC-IGBT in FIG. 30. For this reason, it is possible to suppress the dependence of the high-speed portion (the portion having the low turn-off loss (E_{REC}) and the high on-voltage (V_{F})) of the curve indicating the trade-off characteristic between the turn-off loss (E_{REC}) and the on-voltage (V_{F}) of the diode region 52b on the carrier lifetime control by a charged particles such as an electron beam. In particular, the adverse effect on diode performance due to the impurities such as the oxygen and the carbon in the MCZ wafer becomes significant by performing the carrier lifetime control by the charged particle. For this reason, the configurations of FIGS. 31 to 33 capable of preventing the dependence of the performance of the high-speed portion of the curve indicating the trade-off characteristic between E_{REC} and V_{F} on the carrier lifetime control are effective when the semiconductor substrate 51 is the MCZ wafer.

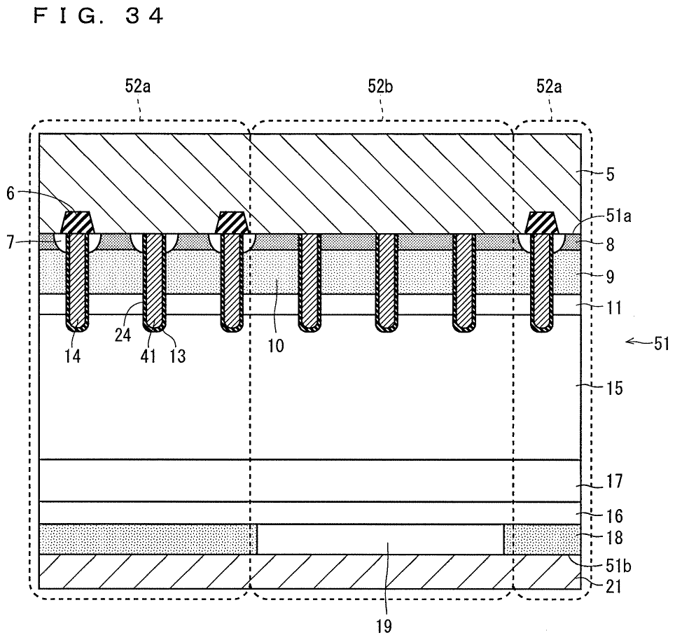

In the configurations of FIGS. 34 to 37, the trench electrodes in some of the trenches 24 are electrically connected to the first electrode 5 in the configurations of FIGS. 30 to 33 to become the dummy electrode 41 that have the same emitter potential as the first electrode 5. According to such the configuration, the oscillation in the unloaded short-circuit state can be prevented by the prevention of the saturation current density of the IGBT region 52a and the control of the capacitance characteristic, so that the reduction of the on-voltage due to the improvement of the short-circuit resistance and the improvement of the carrier concentration on the emitter side can be implemented.

According to the sixth preferred embodiment as described above, the IGBT according to the first to third preferred embodiments and the diode (a) or the diode (b) according to the first to third preferred embodiments are included. According to such the configuration, for example, also in the RC-IGBT, similarly to the first preferred embodiment and the like, the normal on-operation and the improvement of the breakdown resistance during the dynamic operation can be implemented while having the sufficient withstand voltage retention capability in the off-state.

### <Modifications>

In the above description, the semiconductor substrate 51 is made of silicon, but is not limited thereto. For example, the semiconductor substrate 51 may be made of a wide band gap semiconductor such as silicon carbide (SiC). When the semiconductor substrate 51 is made of the wide band gap semiconductor, a stable operation at a high temperature and at a high voltage and an increase in a switching speed can be performed. Furthermore, the MOSFET may be provided instead of the IGBT, and the diode may be a Schottky barrier diode (SBD) or a PN junction diode (PND).

The preferred embodiments can be freely combined, and the preferred embodiments can be appropriately modified or omitted.

Hereinafter, various aspects of the present disclosure will be collectively described as appendixes.

### (Appendix 1)

A semiconductor device comprising:
a semiconductor substrate including a first main surface and a second main surface opposite to the first main surface; and
a first electrode and a second electrode that are provided on the first main surface and the second main surface, respectively,
wherein the semiconductor substrate includes:
a first conductive type drift layer provided between the first main surface and the second main surface;
a semiconductor layer that is connected to the second electrode and includes at least one of a first conductive type first semiconductor layer and a second conductive type second semiconductor layer;
a first conductive type first buffer layer provided between the semiconductor layer and the drift layer; and
a first conductive type second buffer layer that is provided between the first buffer layer and the drift layer and in which a first conductive type impurity concentration is smaller than that of the first buffer layer and is greater than that of the drift layer, and
when a maximum value of an oxygen concentration of the semiconductor substrate calculated using a conversion factor of Old ASTM is maximum [Oᵢ], and an impurity concentration of the first conductive type drift layer is C_{drift},
maximum [Oᵢ]=9.40×10¹⁶×ln(C_{drift})−2.27×10¹⁸ is satisfied.

### (Appendix 2)

The semiconductor device according to Appendix 1, wherein the second buffer layer includes a second-1 buffer layer to a second-n buffer layer that are provided in order from the first buffer layer toward the drift layer and includes C_{2,1} to C_{2,n} as a peak value of the first conductive type impurity concentration, and
C_{2,n}< . . . <C_{2,2}<C_{2,1} is satisfied.

### (Appendix 3)

The semiconductor device according to Appendix 1 or 2, wherein, when a maximum peak value of the first conductive type impurity concentration of the second buffer layer is C₂,
C_{drift}<C₂≤1.0×10¹⁵ cm⁻³ is satisfied.

### (Appendix 4)

The semiconductor device according to any one of Appendixes 1 to 3, wherein, when a maximum peak value of the first conductive type impurity concentration of the first buffer layer is C₁ and the maximum peak value of the first conductive type impurity concentration of the second buffer layer is C₂,
1.0×10⁻⁴≤C₂/C₁≤1.0×10⁻¹ is satisfied.

### (Appendix 5)

The semiconductor device according to Appendix 1, wherein
the second buffer layer is a single layer, and
when a depth of a peak of the first conductive type impurity concentration of the first buffer layer from the second main surface is Xi and a depth of a peak of the first conductive type impurity concentration of the second buffer layer from the second main surface is X₂,
X₁<X₂≤4.0 μm is satisfied.

### (Appendix 6)

The semiconductor device according to any one of Appendixes 1 to 5, wherein the maximum peak value of the first conductive type impurity concentration of the second buffer layer is less than the maximum peak value of the first conductive type impurity concentration of the first buffer layer.

### (Appendix 7)

The semiconductor device according to any one of Appendixes 1 to 6, wherein a first conductive type impurity of the drift layer contains antimony.

### (Appendix 8)

The semiconductor device according to any one of Appendixes 1 to 7, wherein
the semiconductor substrate further includes:
a second conductive type base layer provided closer to the first main surface than the drift layer; and
a first conductive type emitter layer provided closer to the first main surface than the base layer,
a trench electrode including a gate electrode is provided in a trench penetrating the base layer and the emitter layer, and
the semiconductor layer includes the second semiconductor layer connected to the second electrode.

### (Appendix 9)

The semiconductor device according to Appendix 1, wherein, when a carrier lifetime of the drift layer which has no influence on an on-voltage, a carrier lifetime of the first buffer layer, and a carrier lifetime of the second buffer layer are τₜ, τ₁, and τ₂, respectively,
τ₂<τ₁≤τₜ is satisfied.

### (Appendix 10)

The semiconductor device according to any one of Appendixes 1 to 6, wherein
the semiconductor substrate further includes a second conductive type anode layer provided closer to the first main surface than the drift layer, and
the semiconductor layer includes the first semiconductor layer connected to the second electrode.

### (Appendix 11)

The semiconductor device according to any one of Appendixes 1 to 6, wherein
the semiconductor substrate further includes a second conductive type anode layer provided closer to the first main surface than the drift layer, and
the semiconductor layer includes the first semiconductor layer and the second semiconductor layer that are connected to the second electrode.

### (Appendix 12)

A semiconductor device comprising:
a first semiconductor device that is the semiconductor device according to Appendix 8; and
a second semiconductor device that is provided on the semiconductor substrate on which the first semiconductor device is provided, and is the semiconductor device according to Appendix 10.

### (Appendix 13)

A semiconductor device comprising:
a first semiconductor device that is the semiconductor device according to Appendix 8; and
a second semiconductor device that is provided on the semiconductor substrate on which the first semiconductor device is provided, and is the semiconductor device according to Appendix 11.

### (Appendix 14)

The semiconductor device according to Appendix 12 or 13, wherein the semiconductor substrate of the second semiconductor device further includes a second conductive type impurity diffusion layer that is provided between the first electrode and the anode layer and includes a second conductive type impurity concentration higher than that of the anode layer.

### (Appendix 15)

The semiconductor device according to any one of Appendixes 12 to 14, wherein the anode layer is in contact with the first electrode.

### (Appendix 16)

The semiconductor device according to any one of Appendixes 12 to 15, wherein the trench electrode further includes a dummy electrode electrically connected to the first electrode.

### (Appendix 17)

The semiconductor device according to any one of Appendixes 1 to 16, wherein
a first conductive type impurity of the first buffer layer contains arsenic or phosphorus, and
a first conductive type impurity of the second buffer layer contains a proton.

### (Appendix 18)

A method of manufacturing a semiconductor device comprising steps of:
preparing a first conductive type semiconductor substrate including a first main surface on which a first electrode is provided and a second main surface opposite to the first main surface;
forming a first conductive type first buffer layer by implanting a first ion closer to the second main surface than a drift layer that is a part of the semiconductor substrate and performing annealing of the first ions;
implanting a second ion between the first buffer layer and the drift layer;
implanting a third ion onto the side of the second main surface of the first buffer layer;
forming a semiconductor layer including at least one of a first conductive type first semiconductor layer and a second conductive type second semiconductor layer by performing annealing of the third ion;
forming a first conductive type second buffer layer in which a first conductive type impurity concentration is lower than that of the first buffer layer and is greater than that of the drift layer by performing annealing of the second ion; and
forming a second electrode on the second main surface,
wherein, when a maximum value of an oxygen concentration of the semiconductor substrate calculated using a conversion factor of Old ASTM is maximum [Oᵢ], and an impurity concentration of the first conductive type drift layer is C_{drift},
maximum [Oᵢ]=9.40×10¹⁶×ln(C_{drift})−2.27×10¹⁸ is satisfied.

### (Appendix 19)

The method according to Appendix 18, wherein the semiconductor layer includes the first semiconductor layer.

### (Appendix 20)

The method according to Appendix 18, wherein the semiconductor layer includes the second semiconductor layer.

### (Appendix 21)

The method according to Appendix 18, wherein the semiconductor layer includes the first semiconductor layer and the second semiconductor layer.

### (Appendix 22)

The method according to any one of Appendixes 18 to 21, wherein
the second ions is implanted in order of decreasing acceleration energy, and
a dose amount of the second ion implanted with first acceleration energy is lower than a dose amount of the second ion implanted with second acceleration energy lower than the first acceleration energy.

### (Appendix 23)

The method according to any one of Appendixes 18 to 22, wherein
the first ion contains arsenic or phosphorus, and
the second ion contains a proton.

### (Appendix 24)

The method according to any one of Appendixes 18 to 23, wherein the second ions is annealed at a temperature greater than or equal to 375° C. and less than or equal to 425° C. for a time greater than or equal to 90 minutes.

### (Appendix 25)

The method according to any one of Appendixes 18 to 24, wherein the semiconductor substrate includes a semiconductor wafer manufactured by a MCZ method.

### (Appendix 26)

The method according to any one of Appendixes 18 to 25, wherein the semiconductor substrate contains antimony as a first conductive type impurity.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate including a first main surface and a second main surface opposite to the first main surface; and
a first electrode and a second electrode that are provided on the first main surface and the second main surface, respectively,
wherein the semiconductor substrate includes:
a first conductive type drift layer provided between the first main surface and the second main surface;
a semiconductor layer that is connected to the second electrode and includes at least one of a first conductive type first semiconductor layer and a second conductive type second semiconductor layer;
a first conductive type first buffer layer provided between the semiconductor layer and the drift layer; and
a first conductive type second buffer layer that is provided between the first buffer layer and the drift layer and in which a first conductive type impurity concentration is smaller than that of the first buffer layer and is greater than that of the drift layer, and
when a maximum value of an oxygen concentration of the semiconductor substrate calculated using a conversion factor of Old ASTM is maximum [Oᵢ], and an impurity concentration of the first conductive type drift layer is C_{drift},
maximum [Oᵢ]=9.40×10¹⁶×ln(C_{drift})−2.27×10¹⁸ is satisfied.

2. The semiconductor device according to claim 1, wherein the second buffer layer includes a second-1 buffer layer to a second-n buffer layer that are provided in order from the first buffer layer toward the drift layer and includes C_{2,1} to C_{2,n} as a peak value of the first conductive type impurity concentration, and
C_{2,n}< . . . <C_{2,2}<C_{2,1} is satisfied.

3. The semiconductor device according to claim 1, wherein, when a maximum peak value of the first conductive type impurity concentration of the second buffer layer is C₂,
C_{drift}<C₂≤1.0×10¹⁵ cm⁻³ is satisfied.

4. The semiconductor device according to claim 1, wherein, when a maximum peak value of the first conductive type impurity concentration of the first buffer layer is C₁ and the maximum peak value of the first conductive type impurity concentration of the second buffer layer is C₂,
1.0×10⁻⁴≤C₂/C₁≤1.0×10⁻¹ is satisfied.

5. The semiconductor device according to claim 1, wherein
the second buffer layer is a single layer, and
when a depth of a peak of the first conductive type impurity concentration of the first buffer layer from the second main surface is X₁ and a depth of a peak of the first conductive type impurity concentration of the second buffer layer from the second main surface is X₂,
X₁<X₂≤4.0 μm is satisfied.

6. The semiconductor device according to claim 1, wherein the maximum peak value of the first conductive type impurity concentration of the second buffer layer is less than the maximum peak value of the first conductive type impurity concentration of the first buffer layer.

7. The semiconductor device according to claim 1, wherein a first conductive type impurity of the drift layer contains antimony.

8. The semiconductor device according to claim 1, wherein
the semiconductor substrate further includes:
a second conductive type base layer provided closer to the first main surface than the drift layer; and
a first conductive type emitter layer provided closer to the first main surface than the base layer,
a trench electrode including a gate electrode is provided in a trench penetrating the base layer and the emitter layer, and
the semiconductor layer includes the second semiconductor layer connected to the second electrode.

9. The semiconductor device according to claim 1, wherein, when a carrier lifetime of the drift layer which has no influence on an on-voltage, a carrier lifetime of the first buffer layer, and a carrier lifetime of the second buffer layer are τₜ, τ₁, and τ₂, respectively,
τ₂<τ₁≤τₜ is satisfied.

10. The semiconductor device according to claim 1, wherein
the semiconductor substrate further includes a second conductive type anode layer provided closer to the first main surface than the drift layer, and
the semiconductor layer includes the first semiconductor layer connected to the second electrode.

11. The semiconductor device according to claim 1, wherein
the semiconductor substrate further includes a second conductive type anode layer provided closer to the first main surface than the drift layer, and
the semiconductor layer includes the first semiconductor layer and the second semiconductor layer that are connected to the second electrode.

12. A semiconductor device comprising:
a first semiconductor device that is the semiconductor device according to claim 1; and
a second semiconductor device that is provided on the semiconductor substrate on which the first semiconductor device is provided, and is the semiconductor device according to claim 1, wherein
with respect to the first semiconductor device
the semiconductor substrate further includes:
a second conductive type base layer provided closer to the first main surface than the drift layer; and
a first conductive type emitter layer provided closer to the first main surface than the base layer,
a trench electrode including a gate electrode is provided in a trench penetrating the base layer and the emitter layer, and
the semiconductor layer includes the second semiconductor layer connected to the second electrode, and
with respect to the second semiconductor device
the semiconductor substrate further includes a second conductive type anode layer provided closer to the first main surface than the drift layer, and
the semiconductor layer includes the first semiconductor layer connected to the second electrode.

13. A semiconductor device comprising:
a first semiconductor device that is the semiconductor device according to claim 1; and
a second semiconductor device that is provided on the semiconductor substrate on which the first semiconductor device is provided, and is the semiconductor device according to claim 1, wherein
with respect to the first semiconductor device
the semiconductor substrate further includes:
a second conductive type base layer provided closer to the first main surface than the drift layer; and
a first conductive type emitter layer provided closer to the first main surface than the base layer,
a trench electrode including a gate electrode is provided in a trench penetrating the base layer and the emitter layer, and
the semiconductor layer includes the second semiconductor layer connected to the second electrode, and
with respect to the second semiconductor device
the semiconductor substrate further includes a second conductive type anode layer provided closer to the first main surface than the drift layer, and
the semiconductor layer includes the first semiconductor layer and the second semiconductor layer that are connected to the second electrode.

14. The semiconductor device according to claim 12, wherein the semiconductor substrate of the second semiconductor device further includes a second conductive type impurity diffusion layer that is provided between the first electrode and the anode layer and includes a second conductive type impurity concentration higher than that of the anode layer.

15. The semiconductor device according to claim 12, wherein the anode layer is in contact with the first electrode.

16. The semiconductor device according to claim 12, wherein the trench electrode further includes a dummy electrode electrically connected to the first electrode.

17. The semiconductor device according to claim 1, wherein a first conductive type impurity of the first buffer layer contains arsenic or phosphorus, and
a first conductive type impurity of the second buffer layer contains a proton.

18. A method of manufacturing a semiconductor device comprising steps of:
preparing a first conductive type semiconductor substrate including a first main surface on which a first electrode is provided and a second main surface opposite to the first main surface;
forming a first conductive type first buffer layer by implanting a first ion closer to the second main surface than a drift layer that is a part of the semiconductor substrate and performing annealing of the first ions;
implanting a second ion between the first buffer layer and the drift layer;
implanting a third ion onto the side of the second main surface of the first buffer layer;
forming a semiconductor layer including at least one of a first conductive type first semiconductor layer and a second conductive type second semiconductor layer by performing annealing of the third ion;
forming a first conductive type second buffer layer in which a first conductive type impurity concentration is lower than that of the first buffer layer and is greater than that of the drift layer by performing annealing of the second ion; and
forming a second electrode on the second main surface,
wherein, when a maximum value of an oxygen concentration of the semiconductor substrate calculated using a conversion factor of Old ASTM is maximum [Oᵢ], and an impurity concentration of the first conductive type drift layer is C_{drift},
maximum [Oᵢ]=9.40×10¹⁶×ln(C_{drift})−2.27×10¹⁸ is satisfied.

19. The method according to claim 18, wherein the semiconductor layer includes the first semiconductor layer.

20. The method according to claim 18, wherein the semiconductor layer includes the second semiconductor layer.

21. The method according to claim 18, wherein the semiconductor layer includes the first semiconductor layer and the second semiconductor layer.

22. The method according to claim 18, wherein
the second ions is implanted in order of decreasing acceleration energy, and
a dose amount of the second ion implanted with first acceleration energy is lower than a dose amount of the second ion implanted with second acceleration energy lower than the first acceleration energy.

23. The method according to claim 18, wherein
the first ion contains arsenic or phosphorus, and
the second ion contains a proton.

24. The method according to claim 18, wherein the second ions is annealed at a temperature greater than or equal to 375° C. and less than or equal to 425° C. for a time greater than or equal to 90 minutes.

25. The method according to claim 18, wherein the semiconductor substrate includes a semiconductor wafer manufactured by a MCZ method.

26. The method according to claim 18, wherein the semiconductor substrate contains antimony as a first conductive type impurity.
